(19) United States
(12) Patent Application Publication
(10) Pub. No.: US 2025/0098501 A1
(43) Pub. Date: Mar. 20, 2025

(54) DISPLAY DEVICE

(71) Applicant: Samsung Display Co., LTD., Yongin-si (KR)

(72) Inventors: Yong Sub SHIM, Yongin-si (KR); Je Won YOO, Yongin-si (KR); Jung Min CHOI, Yongin-si (KR); Jong Beom HONG, Yongin-si (KR)

(73) Assignee: Samsung Display Co., LTD., Yongin-si (KR)

(21) Appl. No.: 18/637,626

(22) Filed: Apr. 17, 2024

(30) Foreign Application Priority Data
Sep. 15, 2023 (KR) 10-2023-0122992

(51) Int. Cl. H10K 59/80; B60K 35/22; B60K 37/20

(52) U.S. Cl. CPC H10K 59/8792; B60K 35/22; B60K 37/20

(57) ABSTRACT

A display device includes a light emitting element layer, a light control layer on the light emitting element layer and including spaced apart light blocking films and a light transmitting film between the light blocking films, and a first emission area and a second emission area, the light blocking films include, a first louver and a second louver on both sides of a first side of the first emission area, respectively, with the first side between, and a third louver and a fourth louver on both sides of a second side of the second emission area, respectively, with the second side between, a width of the first emission area is different from a width of the second emission area, and a distance between the first side and the first louver is different from a distance between the second side and the third louver.

### CROSS-REFERENCE TO RELATED APPLICATION(S)

This application claims priority to and benefits of Korean Patent Application No. 10-2023-0122992 under 35 U.S.C. § 119 filed on Sep. 15, 2023, in the Korean Intellectual Property Office, the entire contents of which are incorporated herein by reference.

### BACKGROUND

### 1. Technical Field

The disclosure relates to a display device.

### 2. Description of the Related Art

As the information society develops, the demand for display devices for displaying images has increased and diversified. The display devices may be flat panel display devices such as liquid crystal displays (LCDs), field emission displays (FEDs), or light emitting displays (LEDs). A light emitting display device may include an organic light emitting display device including organic light emitting diode elements as light emitting elements or a light emitting diode display device including inorganic light emitting diode elements such as light emitting diodes (LEDs) as light emitting elements.

In a case of a display device for a vehicle, in case that an image displayed on the display device for a vehicle disposed in front of a driver or a passenger is reflected on a windshield of the vehicle at night, the reflected image may disturb the driving of a driver, and thus, it is desirable to control a viewing angle of the image displayed on the display device for a vehicle. It is desirable to control the viewing angle of the image displayed on the display device for a vehicle so that the image displayed on the display device for a vehicle disposed in front of the driver is not provided to the passenger or so that the image displayed on the display device for a vehicle disposed in front of the passenger is not provided to the driver, for the purpose of privacy protection or safe driving.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device in which a difference in luminance for each emission area depending on a viewing angle is minimized.

Aspects of the disclosure also provide a display device in which a color deviation for each emission area depending on a viewing angle is minimized.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a display device may include a light emitting element layer disposed on a substrate, the light emitting element layer including a first light emitting element and a second light emitting element; a light control layer disposed on the light emitting element layer, the light control layer including a plurality of light blocking films spaced apart from each other and a light transmitting film disposed between the plurality of light blocking films; and a first emission area and a second emission area through which light emitted from the first light emitting element and the second light emitting element are emitted, respectively, wherein the plurality of light blocking films include, a first louver and a second louver disposed on both sides of a first side of the first emission area, respectively, with the first side disposed between the first louver and the second louver; and a third louver and a fourth louver disposed on both sides of a second side of the second emission area, respectively, with the second side disposed between the third louver and the fourth louver, a width of the first emission area is different from a width of the second emission area, and a distance between the first side and the first louver is different from a distance between the second side and the third louver.

In an embodiment, the width of the first emission area may be greater than the width of the second emission area.

In an embodiment, a distance between the first louver and the second louver and a distance between the third louver and the fourth louver may be the same.

In an embodiment, the distance between the first side and the first louver may be less than the distance between the second side and the third louver.

In an embodiment, widths of the first louver, the second louver, the third louver and the fourth louver may be the same.

In an embodiment, a length of a portion where the light transmitting film disposed between the first louver and the second louver does not overlap the first emission area may be less than a length of a portion where the light transmitting film disposed between the third louver and the fourth louver does not overlap the second emission area.

In an embodiment, a length by which the light transmitting film disposed between the first louver and the second louver overlaps the first emission area may be greater than a length by which the light transmitting film disposed between the third louver and the fourth louver overlaps the second emission area.

In an embodiment, a distance between the first side and the second louver may be different from a distance between the second side and the fourth louver.

In an embodiment, the distance between the first side and the second louver may be greater than the distance between the second side and the fourth louver.

In an embodiment, the first emission area may include a third side disposed on a side opposite to the first side with the second louver disposed between the third side and the side opposite to the first side, and the second emission area may include a fourth side disposed on a side opposite to the second side with the fourth louver disposed between the fourth side and the side opposite to the second side.

In an embodiment, a distance between the third side and the second louver may be greater than a distance between the fourth side and the fourth louver.

In an embodiment, the first louver may not overlap the first emission area, and the third louver may not overlap the second emission area.

In an embodiment, the second louver may overlap the first emission area, and the fourth louver may overlap the second emission area.

According to an aspect of the disclosure, a display device may include a light emitting element layer disposed on a substrate, the light emitting element layer including a first light emitting element and a second light emitting element; a light control layer disposed on the light emitting element layer, the light emitting element layer including a plurality of light blocking films spaced apart from each other and a light transmitting film disposed between the plurality of light blocking films; and a first emission area and a second emission area through which light emitted from the first light emitting element and the second light emitting element are emitted, respectively, wherein the plurality of light blocking films include, a first louver and a second louver disposed on both sides of a first side of the first emission area, respectively, with the first side disposed between the first louver and the second louver, and a third louver and a fourth louver disposed on both sides of a second side of the second emission area, respectively, with the second side disposed between the third louver and the fourth louver, a width of the first emission area is different from a width of the second emission area, and a distance between the first louver and the second louver is different from a distance between the third louver and the fourth louver.

In an embodiment, the width of the first emission area may be greater than the width of the second emission area.

In an embodiment, the distance between the first louver and the second louver may be less than the distance between the third louver and the fourth louver

In an embodiment, a distance between the first side and the first louver may be less than a distance between the second side and the third louver.

In an embodiment, widths of the first louver, the second louver, the third louver and the fourth louver may be the same.

In an embodiment, a length of a portion where the light transmitting film disposed between the first louver and the second louver does not overlap the first emission area may be less than a length of a portion where the light transmitting film disposed between the third louver and the fourth louver does not overlap the second emission area.

In an embodiment, a distance between the first side and the second louver may be different from a distance between the second side and the fourth louver.

In an embodiment, the distance between the first side and the second louver may be less than the distance between the second side and the fourth louver.

In an embodiment, the first emission area may include a third side disposed on a side opposite to the first side with the second louver disposed between the third side and the side opposite to the first side, and the second emission area may include a fourth side disposed on a side opposite to the second side with the fourth louver disposed between the fourth side and the side opposite to the second side.

In an embodiment, a distance between the third side and the second louver may be greater than a distance between the fourth side and the fourth louver.

In an embodiment, the first louver may not overlap the first emission area, and the third louver may not overlap the second emission area.

In an embodiment, the second louver may overlap the first emission area, and the fourth louver may overlap the second emission area.

With a display device according to an embodiment, it is possible to minimize a difference in luminance for each emission area depending on a viewing angle.

With the display device according to an embodiment, it is possible to minimize a color deviation for each emission area depending on a viewing angle.

The effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is an exploded perspective view illustrating a display device according to an embodiment;

FIG. 2 is a schematic plan view illustrating the display device according to an embodiment;

FIG. 3 is an exploded perspective view illustrating a display device according to an embodiment;

FIG. 4 is a schematic cross-sectional view of the display device taken along line X1-X1′ of FIG. 2;

FIG. 5A is a schematic diagram illustrating a case where the display device according to an embodiment is applied to a vehicle;

FIG. 5B is a schematic diagram illustrating a case where a display device according to an embodiment is applied to a vehicle;

FIG. 6 is a schematic cross-sectional view illustrating an example of a display panel according to an embodiment;

FIG. 7 is a schematic plan view illustrating an example of a pixel of the display device according to an embodiment;

FIG. 8 is a schematic plan view illustrating the pixel and a light control layer of the display device according to an embodiment;

FIG. 9 is an enlarged comparison view of area A and area B of FIG. 8;

FIG. 10 is a schematic cross-sectional view of the display panel taken along line X2-X2′ of FIG. 8;

FIG. 11 is a schematic cross-sectional view of the display panel taken along line X3-X3′ of FIG. 8;

FIG. 12 is a graph illustrating luminance values of emission areas according to a viewing angle in a display device according to the related art;

FIG. 13 is a graph illustrating luminance values of emission areas according to a viewing angle in the display device according to an embodiment;

FIG. 14 is a schematic plan view illustrating a pixel and a light control layer of the display device according to an embodiment;

FIG. 15 is an enlarged comparison view of area A and area B of FIG. 14;

FIG. 16 is a schematic cross-sectional view of the display panel taken along line X4-X4′ of FIG. 14;

FIG. 17 is a schematic cross-sectional view of the display panel taken along line X5-X5′ of FIG. 14; and

FIG. 18 is a graph illustrating luminance values of emission areas according to a viewing angle in the display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in a plan view” means viewing the object from the top, and the phrase “in a schematic cross-sectional view” means viewing a cross-section of which the object is vertically cut from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Hereinafter, embodiments will be described in detail with reference to the accompanying drawings.

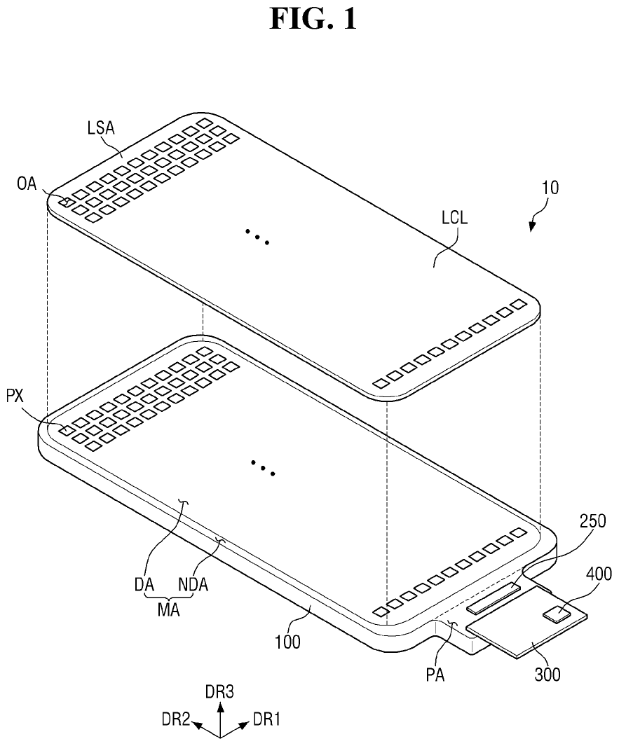

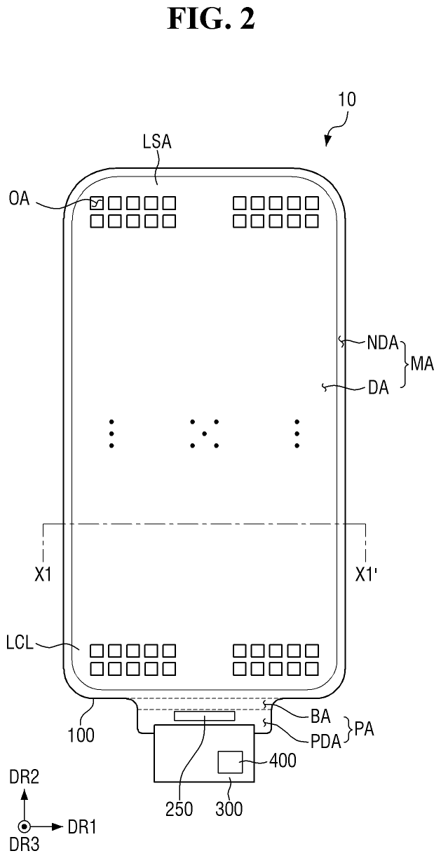

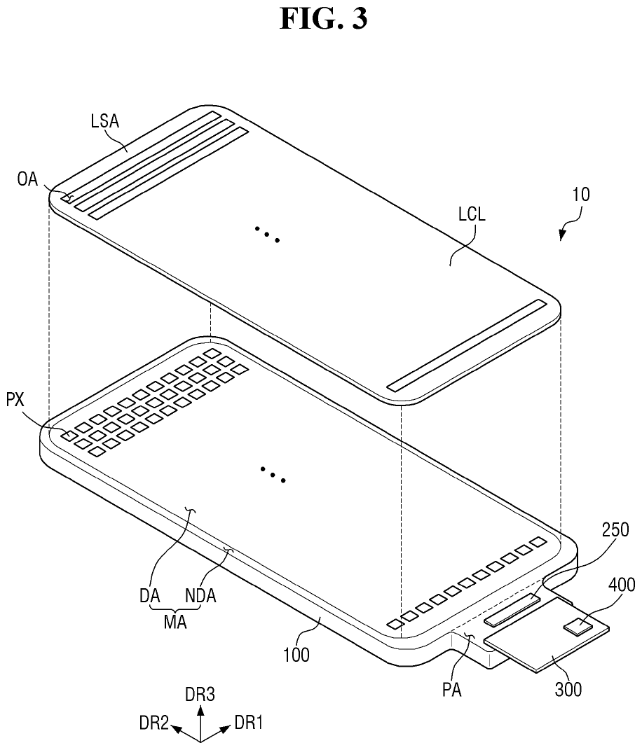

FIG. 1 is an exploded perspective view illustrating a display device according to an embodiment. FIG. 2 is a schematic plan view illustrating the display device according to an embodiment. FIG. 3 is an exploded perspective view illustrating a display device according to an embodiment.

Referring to FIGS. 1 to 3, a display device 10 is a device that displays a moving image or a still image, and may be used as a display screen of various products such as vehicles, televisions, laptop computers, monitors, billboards, and the Internet of Things (IOT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

In an embodiment, in case that the display device 10 is used as a display screen of a vehicle, the display device 10 may be a display for a vehicle. The display for a vehicle may provide various service information such as a convenience function and media information as well as driving information and status information of the vehicle to a user. In case that the display device 10 may include an input device such as a touch panel, the user may operate a driving mode of the vehicle and various functions such as a convenience function through the display device 10.

The display device 10 may be any one of an organic light emitting display, a liquid crystal display, a plasma display panel, a field emission display, an electrophoretic display, an electro-wetting display, a quantum dot light emitting display, and a micro light emitting diode (LED) display. Hereinafter, it will be described that the display device 10 is the organic light emitting display, but the disclosure is not limited thereto.

The display device 10 according to an embodiment may include a display panel 100, a display driving circuit 250, a circuit board 300, and a touch driving circuit 400.

The display panel 100 may include a plurality of pixels PX arranged (or disposed) in a first direction DR1 and a second direction DR2. Each of the pixels PX may have a rectangular, square, or rhombic shape in plan view. For example, as illustrated in FIGS. 1 to 3, each of the pixels PX may have a square shape in plan view. However, each of the pixels PX is not limited thereto, and may have various shapes such as a polygonal shape, a circular shape, and an elliptical shape in plan view.

In the drawings, the first direction DR1 and the second direction DR2 are horizontal directions, respectively, and intersect each other. For example, the first direction DR1 and the second direction DR2 may be orthogonal to each other. A third direction DR3 may be a perpendicular direction intersecting, for example, orthogonal to, the first direction DR1 and the second direction DR2. In the specification, directions indicated by the first to third directions DR1, DR2, and DR3 in the drawings may be referred to as one sides and directions opposite to the one sides may be referred to as the other sides, and unless otherwise specified, the directions indicated by the first to third directions DR1, DR2, and DR3 may include both of the one sides and the other sides.

The display panel 100 may include a main area MA and a protrusion area PA protruding from one side or a side of the main area MA.

The main area MA may be formed in a rectangular shape, in plan view, having short sides in the first direction DR1 and long sides in the second direction DR2 intersecting the first direction DR1. A corner where the short side in the first direction DR1 and the long side in the second direction DR2 meet may be rounded with a selectable curvature or may be right-angled. The shape of the display device 10 in plan view is not limited to the rectangular shape, and may be other polygonal shapes, a circular shape, or an elliptical shape. The main area MA may be formed to be flat, but is not limited thereto, and may include curved surface portions formed at left and right ends thereof. In this case, the curved surface portions may have a constant curvature or a variable curvature.

The main area MA may include a display area DA in which pixels are formed to display an image, and a non-display area NDA, which is a peripheral area of the display area DA.

Scan lines, data lines, and power lines connected to the pixels as well as the pixels may be disposed in the display area DA. In case that the main area MA may include the curved surface portions, the display area DA may be disposed on the curved surface portions. In this case, the image of the display panel 100 may be viewed even on the curved surface portions.

The non-display area NDA may be defined as an area from an outer side of the display area DA to an edge of the display panel 100. A scan driver for applying scan signals to the scan lines and link lines connecting the data lines and the display driving circuit 250 to each other may be disposed in the non-display area NDA.

The protrusion area PA may protrude from one side or a side of the main area MA. For example, the protrusion area PA may protrude from a lower side of the main area MA as illustrated in FIG. 2. A length of the protrusion area PA in the first direction DR1 may be smaller than a length of the main area MA in the first direction DR1.

The protrusion area PA may include a bending area BA and a pad area PDA. In this case, the pad area PDA may be disposed on one side or a side of the bending area BA, and the main area MA may be disposed on the other side of the bending area BA. For example, the pad area PDA may be disposed on a lower side of the bending area BA, and the main area MA may be disposed on an upper side of the bending area BA.

The display panel 100 may be flexibly formed to be curved, bent, folded, or rolled. Therefore, the display panel 100 may be bent in a thickness direction, for example, the third direction DR3, in the bending area BA. In this case, one surface or a surface of the pad area PDA of the display panel 100 faces upward before the display panel 100 is bent, but one surface or a surface of the pad area PDA of the display panel 100 faces downward after the display panel 100 is bent. For this reason, the pad area PDA is disposed below the main area MA, and may thus overlap the main area MA.

Pads electrically connected to the display driving circuit 250 and the circuit board 300 may be disposed in the pad area PDA of the display panel 100.

The display driving circuit 250 outputs signals and voltages for driving the display panel 100. For example, the display driving circuit 250 may supply data voltages to the data lines. The display driving circuit 250 may supply source voltages to the power lines, and may supply scan control signals to the scan driver. The display driving circuit 250 may be formed as an integrated circuit (IC) and mounted on the display panel 100 in the pad area PDA in a chip on glass (COG) manner, a chip on plastic (COP) manner, or an ultrasonic bonding manner, but is not limited thereto. For example, the display driving circuit 250 may be mounted on the circuit board 300.

The pads may include display pads electrically connected to the display driving circuit 250 and touch pads electrically connected to touch lines.

The circuit board 300 may be attached onto the pads using an anisotropic conductive film (ACF). For this reason, lead lines of the circuit board 300 may be electrically connected to the pads. The circuit board 300 may be a flexible printed circuit board, a printed circuit board, or a flexible film such as a chip on film.

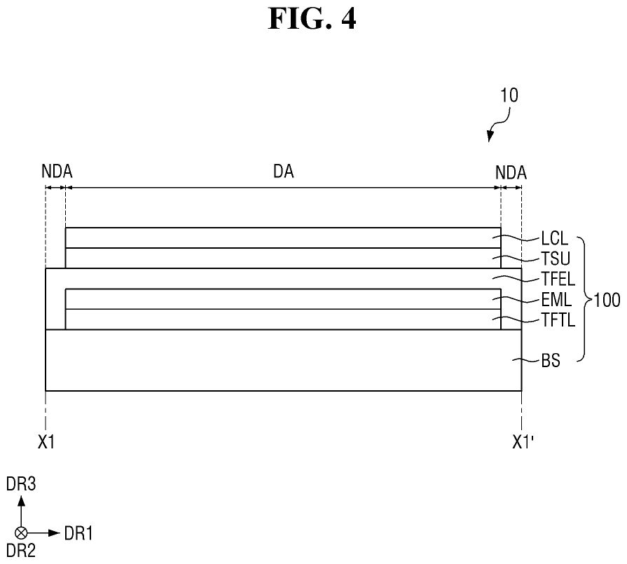

The touch driving circuit 400 may be connected to touch electrodes of a touch sensor layer TSU (see FIG. 4) of the display panel 100. The touch driving circuit 400 applies driving signals to the touch electrodes of the touch sensor layer TSU (see FIG. 4) and measures capacitance values of the touch electrodes. The driving signal may be a signal having a plurality of driving pulses. The touch driving circuit 400 may decide whether or not a touch has been input according to the capacitance values and may calculate touch coordinates where the touch has been input.

The touch driving circuit 400 may be disposed on the circuit board 300. The touch driving circuit 400 may be formed as an integrated circuit (IC) and mounted on the circuit board 300.

In the display device 10 according to an embodiment, the display panel 100 may further include a light control layer LCL.

The light control layer LCL may be directly disposed on the main area MA of the display panel 100. For example, the light control layer LCL may be embedded in the display panel 100 and directly disposed on the main area MA of the display panel 100. The light control layer LCL is embedded in the display panel 100, such that a thickness and a manufacturing cost of the display device 10 may be reduced compared to a case where a separate light control film is attached.

In an embodiment, the light control layer LCL may be disposed on the display area DA of the main area MA. The light control layer LCL may adjust a viewing angle of light emitted from the display panel 100.

However, the disclosure is not limited thereto, and a size of the light control layer LCL may also be greater than a size of the display area DA in plan view. In this case, the light control layer LCL may overlap both the display area DA and the non-display area NDA.

In an embodiment, the light control layer LCL may include transmissive areas OA arranged in the first direction DR1 and the second direction DR2 and a non-transmissive area LSA surrounding the transmissive areas OA. However, the disclosure is not limited thereto, and the non-transmissive areas LSA may be arranged in the first direction DR1 and the second direction DR2 and the transmissive area OA may surround the non-transmissive areas LSA. In FIGS. 1 to 3, for convenience of explanation, a case where the non-transmissive area LSA surrounds transmissive areas OA will be described by way of example.

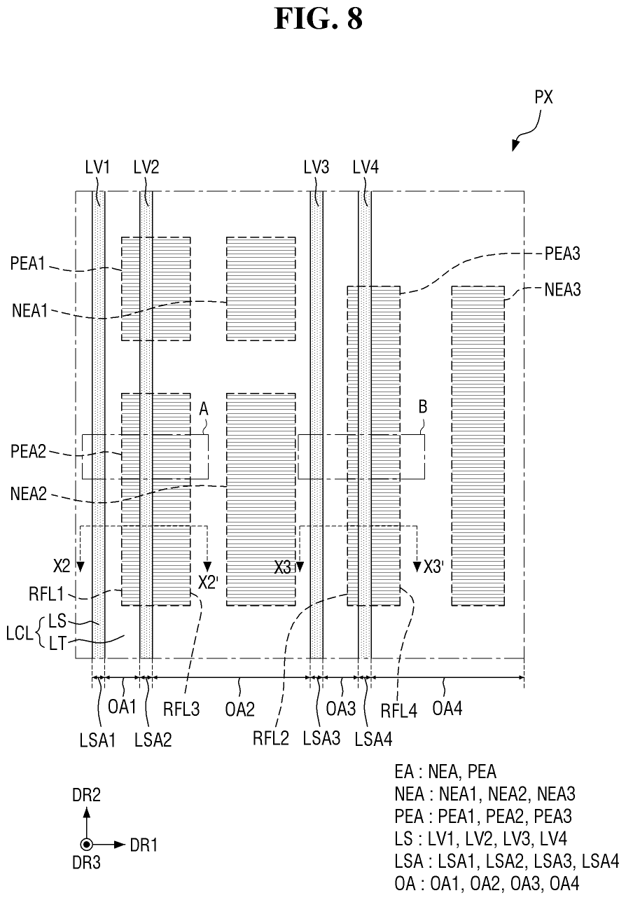

The transmissive areas OA may be areas in which a light blocking film LS (see FIG. 8) is not disposed. The transmissive areas OA are areas transmitting light, and may extend along the third direction DR3.

Each of the transmissive areas OA may have a rectangular shape in plan view as illustrated in FIGS. 1 and 2, but is not limited thereto. Each of the transmissive areas OA may have a circular shape, an elliptical shape, or a polygonal shape in plan view.

In an embodiment, the transmissive areas OA may have a shape in which they extend in the first direction DR1 or the second direction DR2. As an example, as illustrated in FIG. 3, the transmissive areas OA may extend in the first direction DR1 and may be disposed along the second direction DR2. As another example, the transmissive areas OA may extend in the second direction DR2 and may be disposed along the first direction DR1.

As illustrated in FIG. 1, in case that the transmissive areas OA are disposed along the first direction DR1 and the second direction DR2, a viewing angle may be controlled in both the first direction DR1 and the second direction DR2. As illustrated in FIG. 3, in case that the transmissive areas OA are disposed along the first direction DR1 or the second direction DR2, a viewing angle may be controlled in the first direction DR1 or the second direction DR2. For example, an arrangement and a shape of the transmissive areas OA may be variously modified depending on a required viewing angle control direction.

The non-transmissive area LSA may be an area of the light control layer LCL other than the transmissive areas OA. The non-transmissive area LSA may be an area in which the light blocking film LS (see FIG. 8) is disposed.

It has been illustrated in FIGS. 1 to 3 that the non-transmissive area LSA is disposed to surround the transmissive areas OA, but the disclosure is not limited thereto. In an embodiment, the non-transmissive areas LSA may extend in the same direction as the transmissive areas OA and may be disposed alternately with the transmissive areas OA. For example, as illustrated in FIG. 3, in case that the transmissive areas OA extend in the first direction DR1, the non-transmissive areas LSA may extend in the first direction DR1 and may be disposed alternately with the transmissive areas OA in the second direction DR2.

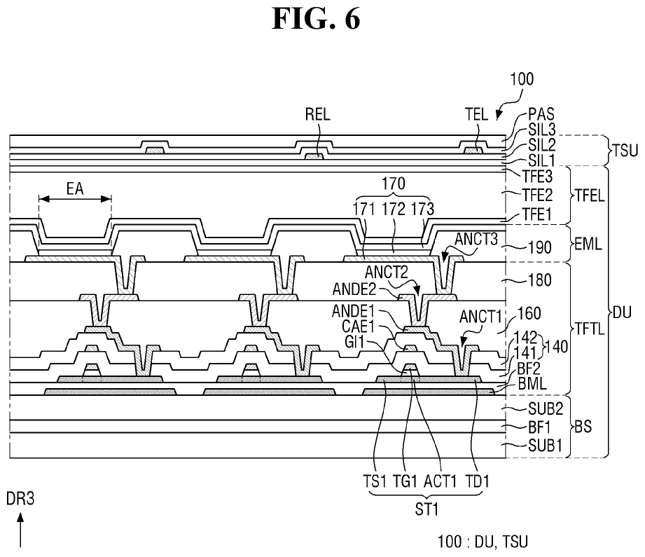

The light control layer LCL may include a light blocking film LS (see FIG. 8) blocking light emitted from a light emitting layer 172 (see FIG. 6) of the display panel 100 and a light transmitting film LT (see FIG. 8) transmitting the light. A detailed structure of the light control layer LCL will be described later with reference to FIG. 8 and the like within the spirit and the scope of the disclosure.

FIG. 4 is a schematic cross-sectional view of the display device taken along line X1-X1′ of FIG. 2.

Referring to FIG. 4, the display device 10 may include the display panel 100 in which the light control layer LCL is embedded. The display panel 100 may include a base member BS, a thin film transistor layer TFTL, a light emitting element layer EML, a thin film encapsulation layer TFEL, a touch sensor layer TSU, and the light control layer LCL.

The base member BS may include a substrate. The substrate may be made of an insulating material such as glass, quartz, or a polymer resin. Examples of the polymer resin may include polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (PI), polycarbonate (PC), cellulose triacetate (CAT), cellulose acetate propionate (CAP), or combinations thereof. By way of example, the substrate may include a metal material.

The substrate may be a rigid substrate or be a flexible substrate that may be bent, folded, and rolled. In case that the substrate is the flexible substrate, the substrate may be made of polyimide (PI), but is not limited thereto.

The thin film transistor layer TFTL may be disposed on the base member BS. The scan lines, the data lines, the power lines, scan control lines, routing lines connecting the pads and the data lines to each other, and the like, as well as thin film transistors of each of the pixels may be formed at the thin film transistor layer TFTL. Each of the thin film transistors may include a gate electrode, a semiconductor layer, a source electrode, and a drain electrode.

The thin film transistor layer TFTL may be disposed in the display area DA and the non-display area NDA. By way of example, the thin film transistors of each of the pixels, the scan lines, the data lines, and the power lines of the thin film transistor layer TFTL may be disposed in the display area DA. The scan control lines and the link lines of the thin film transistor layer TFTL may be disposed in the non-display area NDA.

The light emitting element layer EML may be disposed on the thin film transistor layer TFTL. The light emitting element layer EML may include pixels each including a first electrode, a light emitting layer, and a second electrode, and a pixel defining film defining the pixels. The light emitting layer may be an organic light emitting layer including an organic material. In this case, the light emitting layer may include a hole transporting layer, an organic light emitting layer, and an electron transporting layer. In case that a selectable voltage is applied to the first electrode through the thin film transistor of the thin film transistor layer TFTL and a cathode voltage is applied to the second electrode, holes and electrons move to the organic light emitting layer through the hole transporting layer and the electron transporting layer, respectively, and are combined with each other in the organic light emitting layer to emit light. The pixels of the light emitting element layer EML may be disposed in the display area DA.

The thin film encapsulation layer TFEL may be disposed on the light emitting element layer EML. The thin film encapsulation layer TFEL may serve to prevent oxygen or moisture from permeating into the light emitting element layer EML. To this end, the thin film encapsulation layer TFEL may include at least one inorganic film. The inorganic film may be a silicon nitride layer, a silicon oxynitride layer, a silicon oxide layer, a titanium oxide layer, or an aluminum oxide layer, but is not limited thereto. The thin film encapsulation layer TFEL may serve to protect the light emitting element layer EML from foreign substances such as dust. To this end, the thin film encapsulation layer TFEL may include at least one organic film. The organic film may be made of an acrylic resin, an epoxy resin, a phenolic resin, a polyamide resin, or a polyimide resin, but is not limited thereto.

The thin film encapsulation layer TFEL may be disposed in both the display area DA and the non-display area NDA. By way of example, the thin film encapsulation layer TFEL may be disposed to cover the light emitting element layer EML of the display area DA and the non-display area NDA and cover the thin film transistor layer TFTL of the non-display area NDA.

The touch sensor layer TSU may be disposed on the thin film encapsulation layer TFEL. Since the touch sensor layer TSU is disposed directly on the thin film encapsulation layer TFEL, a thickness of the display device 10 may be reduced compared to a case where a separate touch panel including the touch sensor layer TSU is attached onto the thin film encapsulation layer TFEL.

The touch sensor layer TSU may include touch electrodes for sensing a user's touch in a capacitance manner and touch lines connecting the pads and the touch electrodes to each other. For example, the touch sensor layer TSU may sense the user's touch in a self-capacitance manner or a mutual capacitance manner.

The touch electrodes of the touch sensor layer TSU may be disposed in a touch sensor area overlapping the display area DA. The touch lines of the touch sensor layer TSU may be disposed in a touch peripheral area overlapping the non-display area NDA.

The light control layer LCL may be disposed on the touch sensor layer TSU. The light control layer LCL may be disposed to overlap the display area DA. The light control layer LCL may serve to absorb or block light traveling beyond a selectable angle with respect to the third direction DR3 among light emitted from the light emitting element layer EML. For example, the light control layer LCL may control a viewing angle.

Although not illustrated in FIG. 4, the display device 10 may further include a cover window. The cover window may be additionally disposed on the light control layer LCL, and in this case, the light control layer LCL and the cover window may be attached to each other by a transparent adhesive member such as an optically clear adhesive (OCA) film.

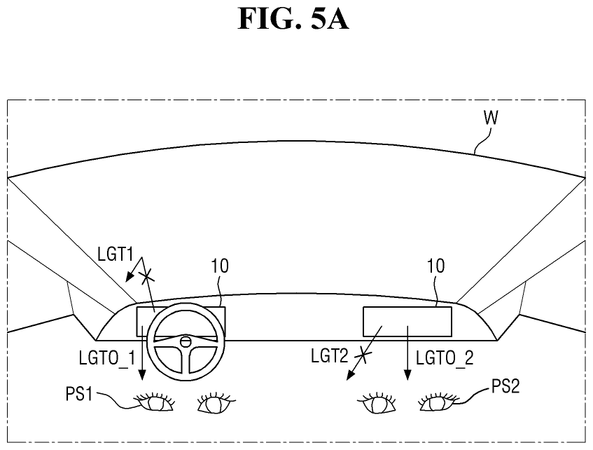

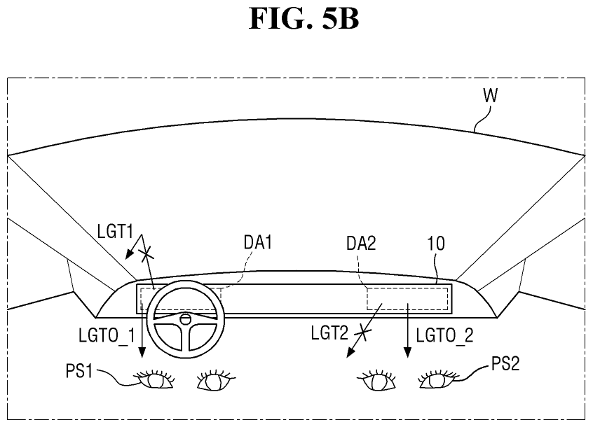

FIG. 5A is a schematic diagram illustrating a case where the display device according to an embodiment is applied to a vehicle. FIG. 5B is a schematic diagram illustrating a case where a display device according to an embodiment is applied to a vehicle.

Referring to FIGS. 5A and 5B, the display device 10 according to an embodiment may be, for example, a display device applied to a vehicle. The vehicle may include a vehicle body forming an appearance of the vehicle and an indoor space defined by the vehicle body. The vehicle body may include a windshield W protecting a driver PS1 and a passenger PS2 from the outside and providing a visual field to the driver PS1. The display device 10 may be provided in the indoor space, as illustrated in FIGS. 5A and 5B.

In an embodiment, the display device 10 may be disposed on a dashboard provided in the indoor space. As an example, as illustrated in FIG. 5A, the display device 10 may be disposed on a dashboard positioned in front of a driver's seat to provide speed information and the like to the driver PS1, may be disposed on a dashboard positioned in front of a passenger seat to provide entertainment information and the like to the passenger PS2, or may be disposed at the center of the dashboard to provide map information and the like within the spirit and the scope of the disclosure. It has been illustrated by way of example in FIG. 5A that the display devices 10 are disposed on the dashboard positioned in front of the driver's seat and the dashboard positioned in front of the passenger seat, respectively.

As another example, as illustrated in FIG. 5B, the display device 10 may extend from the dashboard positioned in front of the driver's seat to the dashboard positioned in front of the passenger seat. For example, the display device 10 may be an integrated display connected from the dashboard positioned in front of the driver's seat to the dashboard positioned in front of the passenger seat. In this case, the display device 10 may include a first display area DA1 positioned in front of the driver's seat and a second display area DA2 positioned in front of the passenger seat. Although not illustrated in FIG. 5B, the display device 10 may further include a third display area between the first display area DA1 and the second display area DA2.

Hereinafter, for convenience of explanation, an embodiment of FIG. 5A will be described by way of example. However, the disclosure is not limited to an embodiment of FIG. 5A, and in the integrated display according to an embodiment of FIG. 5B, the first display area DA1 and the second display area DA2 correspond to the display device 10 in front of the driver's seat and the display device 10 in front of the passenger seat of FIG. 5A, respectively, such that the same technical spirit may be applied to the integrated display according to an embodiment of FIG. 5B.

The driver PS1 may recognize (or view) a display screen of the display device 10 through light LGT0_1 emitted from the display device 10 in front of the driver's seat toward the driver PS1. However, some light LGT1 of the light emitted from the display device 10 disposed in front of the driver's seat may be reflected on the surrounding windshield W and provided to the driver PS1. In this case, an image reflected on the windshield W may disrupt the driving of the driver PS1. On the other hand, in a case of the display device 10 according to an embodiment, by adjusting a viewing angle of the light emitted from the display device 10 with respect to a front direction (a direction frontally facing the driver PS1), for example, a vertical viewing angle, it is possible to prevent some light LGT1 of the light emitted from the display device 10 in front of the driver's seat from being reflected on the surrounding windshield W and being provided to the driver PS1.

The passenger PS2 may recognize (or view) a display screen of the display device 10 through light LGT0_2 emitted from the display device 10 in front of the passenger seat toward the passenger PS2. However, some light LGT2 of the light emitted from the display device 10 disposed in front of the passenger seat may be provided toward the driver PS1. In this case, in case that the vehicle is driving, the viewing of the driver PS1 may be restricted for reasons of safety and the like within the spirit and the scope of the disclosure. In the case of the display device 10 according to an embodiment, by adjusting a viewing angle of the light emitted from the display device 10 with respect to a front direction (a direction frontally facing the passenger PS2), for example, a horizontal viewing angle, it is possible to prevent some light LGT2 of the light emitted from the display device 10 in front of the passenger seat from being provided to the driver PS1.

It has been illustrated in FIG. 5A that the display device 10 in front of the driver's seat adjust the vertical viewing angle and the display device 10 in front of the passenger seat adjusts the horizontal viewing angle, but the disclosure is not limited thereto. As an example, the display device 10 in front of the driver's seat may adjust the horizontal viewing angle, and the display device 10 in front of the passenger seat may adjust the vertical viewing angle. As another example, each of the display device 10 in front of the driver's seat and the display device 10 in front of the passenger seat may adjust both the vertical viewing angle and the horizontal viewing angle.

The viewing angle may be adjusted through the light control layer LCL. The viewing angle may be limited to be in a selectable angle range through a light control layer LCL. As an example, in case that an imaginary line frontally facing the driver PS1 or the passenger PS2 and extending in a direction perpendicular to a display surface of the display device 10 is a normal, the viewing angle may be an angle within about 35° from the normal. In an embodiment, the angle within about 35° from the normal may be defined as an effective viewing angle, but the disclosure is not limited thereto.

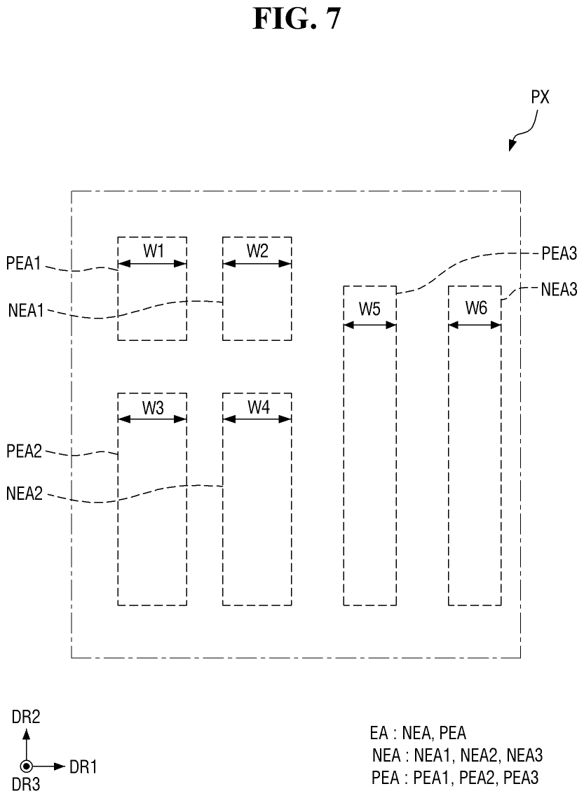

In addition, in case that the vehicle is stopping, some light LGT2 of the light emitted from the display device 10 in front of the passenger seat may be provided to the driver PS1 again. For example, it is possible to freely switch between a case of not controlling the viewing angle of the display device 10 and case of controlling the viewing angle of the display device 10. To this end, the display device 10 may include a pixel PX (see FIG. 7) structure capable of implementing a normal mode and a privacy mode. This will be described in detail later with reference to FIG. 7.

FIG. 6 is a schematic cross-sectional view illustrating an example of a display panel according to an embodiment.

Referring to FIG. 6, the display panel 100 may include a display layer DU and a touch sensor layer TSU. The display layer DU may include a base member BS, a thin film transistor layer TFTL, a light emitting element layer EML, and a thin film encapsulation layer TFEL.

The base member BS may include a first substrate SUB1, a first buffer film BF1 disposed on the first substrate SUB1, and a second substrate SUB2 disposed on the first buffer film BF1.

Each of the first substrate SUB1 and the second substrate SUB2 may be made of an insulating material such as glass, quartz, or a polymer resin. Examples of the polymer resin may include polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (PI), polycarbonate (PC), cellulose triacetate (CAT), cellulose acetate propionate (CAP), or combinations thereof. By way of example, each of the first substrate SUB1 and the second substrate SUB2 may include a metal material.

Each of the first substrate SUB1 and the second substrate SUB2 may be a rigid substrate or be a flexible substrate that may be bent, folded, and rolled. In case that each of the first substrate SUB1 and the second substrate SUB2 is the flexible substrate, each of the first substrate SUB1 and the second substrate SUB2 may be made of polyimide (PI), but is not limited thereto.

The first buffer film BF1 is a film for protecting a first thin film transistor ST1 and a light emitting layer 172 from moisture permeating through the first substrate SUB1 and the second substrate SUB2 vulnerable to moisture permeation. The first buffer film BF1 may include a plurality of inorganic films that are alternately stacked each other. For example, the first buffer film BF1 may be formed as multiple films in which one or more inorganic films of a silicon nitride layer, a silicon oxynitride layer, a silicon oxide layer, a titanium oxide layer, and an aluminum oxide layer are alternately stacked each other.

The thin film transistor layer TFTL may include bottom metal layers BML, a second buffer film BF2, first thin film transistors ST1, a first gate insulating film GI1, a first interlayer insulating film 141, first capacitor electrodes CAE1, a second interlayer insulating film 142, first anode connection electrodes ANDE1, a first organic film 160, second anode connection electrodes ANDE2, and a second organic film 180. The first interlayer insulating film 141 and the second interlayer insulating film 142 may be collectively referred to as an interlayer insulating film 140.

The bottom metal layer BML may be disposed on the second substrate SUB2. The bottom metal layer BML may be disposed to overlap a first active layer ACT1 of the first thin film transistor ST1 in the third direction DR3 in order to prevent a leakage current from being generated in case that light is incident on the first active layer ACT1 of the first thin film transistor ST1. The bottom metal layer BML may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. The bottom metal layer BML may be omitted.

The second buffer film BF2 may be disposed on the bottom metal layer BML. The second buffer film BF2 is a film for protecting the first thin film transistor ST1 and the light emitting layer 172 from moisture permeating through the first substrate SUB1 and the second substrate SUB2 vulnerable to moisture permeation. The second buffer film BF2 may include a plurality of inorganic films that are alternately stacked each other. For example, the second buffer film BF2 may be formed as multiple films in which one or more inorganic films of a silicon nitride layer, a silicon oxynitride layer, a silicon oxide layer, a titanium oxide layer, and an aluminum oxide layer are alternately stacked each other.

The first active layer ACT1 of the first thin film transistor ST1 may be disposed on the second buffer film BF2. The first active layer ACT1 of the first thin film transistor ST1 may include polycrystalline silicon, single crystal silicon, low-temperature polycrystalline silicon, amorphous silicon, or an oxide semiconductor. The first active layer ACT1 of the first thin film transistor ST1 exposed without being covered by the first gate insulating film GI1 is doped with impurities or ions, and may thus have conductivity. Therefore, a first source electrode TS1 and a first drain electrode TD1 of the first active layer ACT1 of the first thin film transistor ST1 may be formed.

The first gate insulating film GI1 may be disposed on the first active layer ACT1 of the first thin film transistor ST1. It has been illustrated in FIG. 6 that the first gate insulating film GI1 is disposed between a first gate electrode TG1 and the first active layer ACT1 of the first thin film transistor ST1, but the disclosure is not limited thereto. The first gate insulating film GI1 may also be disposed between the first interlayer insulating film 141 and the first active layer ACT1 and between the first interlayer insulating film 141 and the second buffer film BF2. The first gate insulating film GI1 may be formed as an inorganic film such as a silicon nitride layer, a silicon oxynitride layer, a silicon oxide layer, a titanium oxide layer, or an aluminum oxide layer.

The first gate electrode TG1 of the first thin film transistor ST1 may be disposed on the first gate insulating film GI1. The first gate electrode TG1 of the first thin film transistor ST1 may overlap the first active layer ACT1 in the third direction DR3. The first gate electrode TG1 of the first thin film transistor ST1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first interlayer insulating film 141 may be disposed on the first gate electrode TG1 of the first thin film transistor ST1. The first interlayer insulating film 141 may be formed as an inorganic film such as a silicon nitride layer, a silicon oxynitride layer, a silicon oxide layer, a titanium oxide layer, or an aluminum oxide layer. The first interlayer insulating film 141 may include a plurality of inorganic films.

The first capacitor electrodes CAE1 may be disposed on the first interlayer insulating film 141. The first capacitor electrode CAE1 may overlap the first gate electrode TG1 of the first thin film transistor ST1 in the third direction (Z-axis direction). Since the first interlayer insulating film 141 has a selectable dielectric constant, a capacitor may be formed by the first capacitor electrode CAE1, the first gate electrode TG1, and the first interlayer insulating film 141 disposed between the first capacitor electrode CAE1 and the first gate electrode TG1. The first capacitor electrode CAE1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second interlayer insulating film 142 may be disposed on the first capacitor electrodes CAE1. The second interlayer insulating film 142 may be formed as an inorganic film such as a silicon nitride layer, a silicon oxynitride layer, a silicon oxide layer, a titanium oxide layer, or an aluminum oxide layer. The second interlayer insulating film 142 may include a plurality of inorganic films.

The first anode connection electrodes ANDE1 may be disposed on the second interlayer insulating film 142. The first anode connection electrode ANDE1 may be connected to the first drain electrode TD1 of the first thin film transistor ST1 through a first anode contact hole ANCT1 penetrating through the first interlayer insulating film 141 and the second interlayer insulating film 142 to expose the first drain electrode TD1 of the first thin film transistor ST1. The first anode connection electrode ANDE1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first organic film 160 for planarization may be disposed on the first anode connection electrodes ANDE1. The first organic film 160 may be formed as an organic film made of an acrylic resin, an epoxy resin, a phenolic resin, a polyamide resin, a polyimide resin, or the like within the spirit and the scope of the disclosure.

The second anode connection electrodes ANDE2 may be disposed on the first organic film 160. The second anode connection electrode ANDE2 may be connected to the first anode connection electrode ANDE1 through a second anode contact hole ANCT2 penetrating through the first organic film 160 to expose the first anode connection electrode ANDE1. The second anode connection electrode ANDE2 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second organic film 180 may be disposed on the second anode connection electrodes ANDE2. The second organic film 180 may be formed as an organic film made of an acrylic resin, an epoxy resin, a phenolic resin, a polyamide resin, a polyimide resin, or the like within the spirit and the scope of the disclosure.

It has been illustrated in FIG. 6 that the first thin film transistor ST1 is formed in a top gate type in which the first gate electrode TG1 is positioned above the first active layer ACT1, but the disclosure is not limited thereto. The first thin film transistor ST1 may be formed in a bottom gate type in which the first gate electrode TG1 is positioned below the first active layer ACT1 or a double gate type in which the first gate electrodes TG1 are positioned both above and below the first active layer ACT1.

The light emitting element layer EML may be disposed on the second organic film 180. The light emitting element layer EML may include light emitting elements 170 and a bank 190. Each of the light emitting elements 170 may include a first light emitting electrode 171, the light emitting layer 172, and a second light emitting electrode 173.

The first light emitting electrode 171 may be formed on the second organic film 180. The first light emitting electrode 171 may be connected to the second anode connection electrode ANDE2 through a third anode contact hole ANCT3 penetrating through the second organic film 180 to expose the second anode connection electrode ANDE2.

In a top emission structure in which light is emitted toward the second light emitting electrode 173 based on the light emitting layer 172, the first light emitting electrode 171 may be made of a metal material having high reflectivity, such as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO. The APC alloy is an alloy of silver (Ag), palladium (Pd), and copper (Cu).

The bank 190 may be formed to partition the first light emitting electrodes 171 on the second organic film 180 in order to serve to define emission areas EA. The bank 190 may include openings exposing at least portions of upper surfaces of the first light emitting electrodes 171. The bank 190 may be formed to cover edges of the first light emitting electrodes 171. The bank 190 may be formed as an organic film made of an acrylic resin, an epoxy resin, a phenolic resin, a polyamide resin, a polyimide resin, or the like within the spirit and the scope of the disclosure.

The emission area EA refers to an area in which the first light emitting electrode 171, the light emitting layer 172, and the second light emitting electrode 173 are sequentially stacked and holes from the first light emitting electrode 171 and electrons from the second light emitting electrode 173 are combined with each other in the light emitting layer 172 to emit light. The emission area EA may be defined by the opening of the bank 190.

The light emitting layer 172 is formed on the first light emitting electrode 171 and the bank 190. The light emitting layer 172 may be disposed in the opening of the bank 190, but is not limited thereto. The light emitting layer 172 may include an organic material to emit light of a selectable color. For example, the light emitting layer 172 may include a hole transporting layer, an organic material layer, and an electron transporting layer.

The second light emitting electrode 173 may be disposed on the light emitting layer 172. The second light emitting electrode 173 may be formed to cover the light emitting layer 172. The second light emitting electrode 173 may be a common layer formed in common in all emission areas EA. Although not illustrated in FIG. 6, in an embodiment, a capping layer may be formed on the second light emitting electrode 173.

In the top emission structure, the second light emitting electrode 173 may be made of transparent conductive oxide (TCO) such as ITO or indium zinc oxide (IZO) capable of transmitting light or a semi-transmissive conductive material such as magnesium (Mg), silver (Ag), or an alloy of magnesium (Mg) and silver (Ag). In case that the second light emitting electrode 173 is made of the semi-transmissive conductive material, light emission efficiency may be increased by a micro cavity.

The thin film encapsulation layer TFEL may be disposed on the second light emitting electrode 173. The thin film encapsulation layer TFEL may include at least one inorganic film in order to prevent oxygen or moisture from permeating into the light emitting element layer. The thin film encapsulation layer TFEL may include at least one organic film in order to protect the light emitting element layer from foreign substances such as dust. For example, the thin film encapsulation layer TFEL may include a first encapsulation film TFE1, a second encapsulation film TFE2, and a third encapsulation film TFE3.

The first encapsulation film TFE1 (for example, a first inorganic encapsulation film) may be disposed on the second light emitting electrode 173. The first encapsulation film TFE1 may be a single-layer or multilayer inorganic film. The first encapsulation film TFE1 may be formed as multiple films in which one or more inorganic films of a silicon nitride layer, a silicon oxynitride layer, a silicon oxide layer, a titanium oxide layer, and an aluminum oxide layer are alternately stacked each other or a single film.

The second encapsulation film TFE2 (for example, a first organic encapsulation film) may be disposed on the first encapsulation film TFE1. The second encapsulation film TFE2 may be a single-layer or multilayer organic film. The second encapsulation film TFE2 may include a polymer-based material. The polymer-based material may include polyethylene terephthalate, polyethylene naphthalate, polycarbonate, polyimide, polyethylene sulfonate, polyoxymethylene, polyarylate, hexamethyldisiloxane, and an acrylic resin (for example, polymethyl methacrylate, polyacrylic acid, etc.), or any combinations thereof.

The third encapsulation film TFE3 (for example, a second inorganic encapsulation film) may be disposed on the second encapsulation film TFE2. The third encapsulation film TFE3 may be a single-layer or multilayer inorganic film. The third encapsulation film TFE3 may include the same material as the first encapsulation film TFE1. For example, the third encapsulation film TFE3 may be formed as multiple films in which one or more inorganic films of a silicon nitride layer, a silicon oxynitride layer, a silicon oxide layer, a titanium oxide layer, and an aluminum oxide layer are alternately stacked each other or a single film.

The touch sensor layer TSU may be disposed on the thin film encapsulation layer TFEL. The touch sensor layer TSU may include a plurality of touch electrodes for sensing a user's touch in a capacitance manner and touch lines connecting the plurality of touch electrodes and a touch driver to each other. For example, the touch sensor layer TSU may sense the user's touch in a mutual capacitance manner or a self-capacitance manner.

In an embodiment, the touch sensor layer TSU may be disposed on a separate substrate disposed on the display layer DU. In this case, the substrate supporting the touch sensor layer TSU may be an encapsulation member encapsulating the display layer DU.

The plurality of touch electrodes of the touch sensor layer TSU may be disposed in a touch sensor area overlapping the display area. The touch lines of the touch sensor layer TSU may be disposed in a touch peripheral area overlapping the non-display area.

The touch sensor layer TSU may include a first touch insulating film SIL1, first touch electrodes REL, a second touch insulating film SIL2, second touch electrodes TEL, and a third touch insulating film SIL3.

The first touch insulating film SIL1 may be disposed on the thin film encapsulation layer TFEL. The first touch insulating film SIL1 may have insulating and optical functions. The first touch insulating film SIL1 may include at least one inorganic film. For example, the first touch insulating film SIL1 may be an inorganic film including at least one of a silicon nitride layer, a silicon oxynitride layer, a silicon oxide layer, a titanium oxide layer, and an aluminum oxide layer. Optionally, the first touch insulating film SIL1 may be omitted.

The first touch electrodes REL may be disposed on the first touch insulating film SIL1. The first touch electrode REL may not overlap the light emitting element 170. The first touch electrode REL may be formed as a single layer made of molybdenum (Mo), titanium (Ti), copper (Cu), aluminum (Al), or indium tin oxide (ITO) or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The second touch insulating film SIL2 may cover the first touch electrodes REL and the first touch insulating film SIL1. The second touch insulating film SIL2 may have insulating and optical functions. For example, the second touch insulating film SIL2 may be made of the material described in the first touch insulating film SIL1.

The second touch electrodes TEL may be disposed on the second touch insulating film SIL2. The second touch electrode TEL may not overlap the light emitting element 170. The second touch electrode TEL may be formed as a single layer made of molybdenum (Mo), titanium (Ti), copper (Cu), aluminum (Al), or indium tin oxide (ITO) or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The third touch insulating film SIL3 may cover the second touch electrodes TEL and the second touch insulating film SIL2. The third touch insulating film SIL3 may have insulating and optical functions. The third touch insulating film SIL3 may be made of the material described in the second touch insulating film SIL2.

In an embodiment, the first touch insulating film SIL1, the second touch insulating film SIL2, and the third touch insulating film SIL3 may be organic films. For example, the first touch insulating film SIL1, the second touch insulating film SIL2, and the third touch insulating film SIL3 may be organic films made of an acrylic resin, an epoxy resin, a phenolic resin, a polyamide resin, a polyimide resin, or the like within the spirit and the scope of the disclosure.

The touch sensor layer TSU may further include a planarization film PAS for planarization. The planarization film PAS may be formed as an organic film made of an acrylic resin, an epoxy resin, a phenolic resin, a polyamide resin, a polyimide resin, or the like within the spirit and the scope of the disclosure.

FIG. 7 is a schematic plan view illustrating an example of a pixel of the display device according to an embodiment.

Referring to FIG. 7 and FIG. 6, the pixel PX may include an emission area EA, which is an area through which light emitted by the light emitting element 170 is emitted. The emission area EA may be defined by the bank 190. For example, a plurality of emission areas EA may be areas overlapping the light emitting layers 172 disposed in the openings of the bank 190. The emission area EA may be an area in which the first light emitting electrode 171, the light emitting layer 172, and the second light emitting electrode 173 are sequentially stacked while overlapping each other.

In an embodiment, the emission area EA may include a normal mode area NEA (for example, a first light emitting mode area) and a privacy mode area PEA (for example, a second light emitting mode area).

In case that a user drives the display device 10 in a normal mode, light emitting elements disposed in the normal mode area NEA may emit light, and light emitting elements disposed in the privacy mode area PEA may not emit light. In case that the user drives the display device 10 in a privacy mode, the light emitting elements disposed in the normal mode area NEA may not emit light, and the light emitting elements disposed in the privacy mode area PEA may emit light.

However, the disclosure is not limited thereto, and in a case of the normal mode, both of the light emitting elements disposed in the normal mode area NEA and the privacy mode area PEA may emit light.

The normal mode area NEA and the privacy mode area PEA may include first to third emission areas NEA1, NEA2, NEA3, PEA1, PEA2, and PEA3, respectively.

It has been illustrated in FIG. 7 that each of the normal mode area NEA and the privacy mode area PEA may include three types of emission areas EA, but the disclosure is not limited thereto. For example, each of the normal mode area NEA and the privacy mode area PEA may include fewer or more emission areas EA than three types of emission areas EA.

In an embodiment, as illustrated in FIG. 7, the first to third emission areas NEA1, NEA2, and NEA3 of the normal mode area NEA may be disposed side by side with the first to third emission areas PEA1, PEA2, and PEA3 of the privacy mode area PEA on one sides of the first to third emission areas PEA1, PEA2, and PEA3 of the privacy mode area PEA, respectively. For example, the first emission area NEA1 of the normal mode area NEA may be disposed on one side or a side of the first emission area PEA1 of the privacy mode area PEA in the first direction DR1, the second emission area NEA2 of the normal mode area NEA may be disposed on one side or a side of the second emission area PEA2 of the privacy mode area PEA in the first direction DR1, and the third emission area NEA3 of the normal mode area NEA may be disposed on one side or a side of the third emission area PEA3 of the privacy mode area PEA in the first direction DR1.

The first emission area NEA1 of the normal mode area NEA and the second emission area NEA2 of the normal mode area NEA may be disposed side by side in the second direction DR2, and the first emission area PEA1 of the privacy mode area PEA and the second emission area PEA2 of the privacy mode area PEA may be disposed side by side in the second direction DR2. The third emission area NEA3 of the normal mode area NEA may be disposed on one side or a side of the first and second emission areas NEA1 and NEA2 of the normal mode area NEA in the first direction DR1. The third emission area PEA3 of the privacy mode area PEA may be disposed on one side or a side of the first and second emission areas PEA1 and PEA2 of the privacy mode area PEA in the first direction DR1.

However, an arrangement of the first to third emission areas NEA1, NEA2, NEA3, PEA1, PEA2 and, PEA3 of each of the normal mode area NEA and the privacy mode area PEA is not limited thereto, and may be variously modified.

In an embodiment, the first emission areas NEA1 and PEA1 may emit light of a first color, the second emission areas NEA2 and PEA2 may emit light of a second color, and the third emission areas NEA3 and PEA3 may emit light of a third color. The light of the first color may be light of a red wavelength band, the light of the second color may be light of a green wavelength band, and the light of the third color may be light of a blue wavelength band. The red wavelength band may be a wavelength band in a range of about 600 nm to about 750 nm, the green wavelength band may be a wavelength band in a range of about 480 nm to about 560 nm, and the blue wavelength band may be a wavelength band in a range of about 370 nm to about 460 nm, but the disclosure is not limited thereto.

Each of the first to third emission areas NEA1, NEA2, NEA3, PEA1, PEA2, and PEA3 may have a rectangular, square, or rhombic shape in plan view. For example, as illustrated in FIG. 7, each of the first to third emission areas NEA1, NEA2, NEA3, PEA1, PEA2, and PEA3 may have a rectangular shape, but is not limited thereto.

In an embodiment, areas of the first to third emission areas NEA1, NEA2, NEA3, PEA1, PEA2, and PEA3 may be different from each other. For example, areas of the third emission area NEA3 and PEA3 may be greater than areas of the first and second emission area NEA1, NEA2, PEA1, and PEA2, but are not limited thereto. Accordingly, by disposing the light emitting elements 170 of colors with relatively low lifespans in great areas, a difference in lifespan between the light emitting elements of respective colors may be minimized. As an example, the light emitting elements may have longer lifespans in the order of a red light emitting element, a green light emitting element, and a blue light emitting element, and may be disposed in the first to third emission areas NEA1, NEA2, NEA3, PEA1, PEA2, and PEA3 in the above order, respectively.

In an embodiment, widths W5 and W6 of the third emission areas PEA3 and NEA3 may be smaller than widths W1 and W2 of the first emission areas PEA1 and NEA1 and widths W3 and W4 of the second emission areas PEA2 and NEA2. For example, for design reasons such as a line arrangement of a circuit layer and color deviation improvement, the widths W5 and W6 of the third emission areas PEA3 and NEA3 may be smaller than the widths W1, W2, W3, and W4 of the first and second emission areas PEA1, NEA1, PEA2, and NEA2. In this case, in order to make the areas of the third emission area PEA3 and NEA3 greater than the areas of the first and second emission areas PEA1, NEA1, PEA2, and NEA2, lengths of the second emission area PEA3 and NEA3 in the second direction DR2 may be greater than lengths of the first and second emission areas PEA1, NEA1, PEA2, and NEA2 in the second direction DR2.

The display device 10 according to an embodiment may switch a viewing angle control function between turn-on and turn-off states depending on a driving method by including each of the normal mode area NEA and the privacy mode area PEA. In relation to this, an arrangement relationship of the light control layer LCL with respect to the normal mode area NEA and the privacy mode area PEA will hereinafter be described.

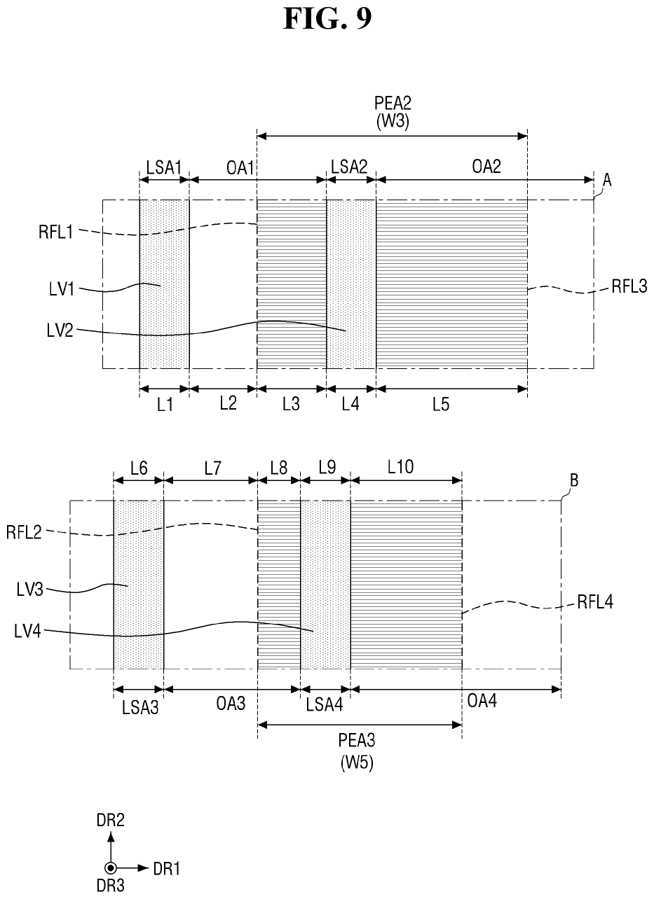

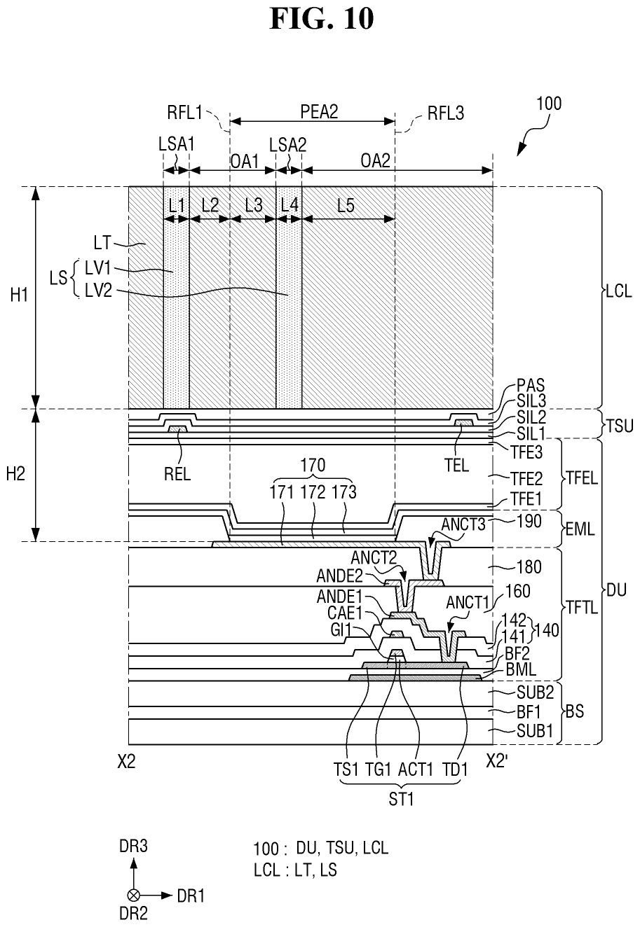

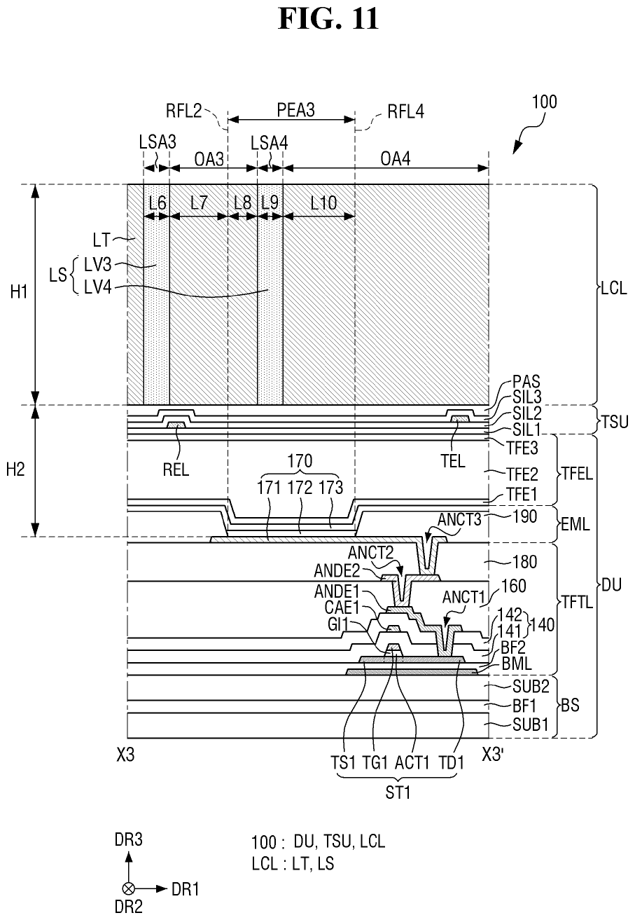

FIG. 8 is a schematic plan view illustrating the pixel and a light control layer of the display device according to an embodiment. FIG. 9 is an enlarged comparison view of area A and area B of FIG. 8. FIG. 10 is a schematic cross-sectional view of the display panel taken along line X2-X2′ of FIG. 8. FIG. 11 is a schematic cross-sectional view of the display panel taken along line X3-X3′ of FIG. 8.

Referring to FIGS. 8 to 11, the emission areas EA may overlap the transmissive area OA and/or the non-transmissive area LSA in the third direction DR3. For example, the first to third emission areas NEA1, NEA2, NEA3, PEA1, PEA2, and PEA3 may overlap the transmissive area OA and/or the non-transmissive area LSA in the third direction DR3.

The transmissive area OA may be an area in which the light blocking film LS of the light control layer LCL is not disposed. The non-transmissive area LSA may be an area in which the light blocking film LS of the light control layer LCL is disposed.

As illustrated in FIG. 8, the normal mode area NEA may overlap the transmissive area OA. The privacy mode area PEA may overlap the transmissive area OA and the non-transmissive area LSA.

It has been illustrated by way of example in FIG. 8 that the transmissive area OA and the non-transmissive area LSA extend in the second direction DR2, but the disclosure is not limited thereto. For example, the transmissive area OA and the non-transmissive area LSA may also extend in the first direction DR1 or extend in both the first direction DR1 and the second direction DR2. Hereinafter, for convenience of explanation, it will be described by way of example that the transmissive area OA and the non-transmissive area LSA extend in the second direction DR2.

In the normal mode area NEA, the transmissive area OA may extend along the second direction DR2. In the privacy mode area PEA, the transmissive areas OA and the non-transmissive areas LSA may extend along the second direction DR2, and may be alternately disposed in the first direction DR1.

As illustrated in FIGS. 10 and 11, the light control layer LCL may be disposed on the display layer DU or the touch sensor layer TSU. The light control layer LCL may control a viewing angle of the light emitted from the light emitting layer 172. For example, in case that the light emitted from the light emitting layer 172 travels at a selectable angle or less with respect to the third direction DR3, the light may be emitted to the outside. On the other hand, in case that the light emitted from the light emitting layer 172 travels beyond a selectable angle with respect to the third direction DR3, the light may be absorbed or blocked by the light blocking film LS and may not be emitted to the outside.

The light control layer LCL may include the light transmitting film LT and the light blocking film LS.

The light blocking film LS may be disposed on the display layer DU or the touch sensor layer TSU. The light blocking film LS may be disposed in the non-transmissive area LSA. The light blocking film LS may absorb or block the light emitted from the light emitting layer 172. The light blocking film LS may include a light blocking organic material. For example, the light blocking film LS is made of a photosensitive resin capable of absorbing or blocking light, and may include an organic material including an organic black pigment such as carbon black.

The light blocking film LS may extend in the first direction DR1 and/or the second direction DR2. The light blocking film LS may not overlap the normal mode area NEA and may overlap the privacy mode area PEA, in the third direction DR3. For example, the light blocking film LS may not overlap the first to third emission areas NEA1, NEA2, and NEA3 of the normal mode area NEA and may overlap the first to third emission areas PEA1, PEA2, and PEA3 of the privacy mode area PEA, in the third direction DR3.

The display device 10 according to an embodiment may switch the viewing angle control function between the turn-on and turn-off states depending on which of the normal mode area NEA or the privacy mode area PEA is driven by including the light blocking film LS that does not overlap the normal mode area NEA and overlaps the privacy mode area PEA.

The light transmitting film LT may be disposed on the display layer DU or the touch sensor layer TSU. The light transmitting film LT may be disposed in the transmissive area OA. The light transmitting film LT may transmit the light emitted from the light emitting layer 172. The light transmitting film LT may include a transparent organic material. For example, the light transmitting film LT may include an organic film made of an acrylic resin, an epoxy resin, a phenolic resin, a polyamide resin, a polyimide resin, or the like within the spirit and the scope of the disclosure. In an embodiment, the light transmitting film LT may include silicon oxynitride or silicon oxide.

The light transmitting film LT may extend in the first direction DR1 and/or the second direction DR2. The light transmitting film LT may overlap the normal mode area NEA and the privacy mode area PEA in the third direction DR3. For example, the light transmitting film LT may overlap the first to third emission areas NEA1, NEA2, and NEA3 of the normal mode area NEA and the first to third emission areas PEA1, PEA2, and PEA3 of the privacy mode area PEA in the third direction DR3.

In an embodiment, as illustrated in FIGS. 10 and 11, a thickness H1 of the light control layer LCL may be in a range of about 10 μm to about 50 μm, but is not limited thereto. For example, the thickness H1 of the light control layer LCL may be about 35 μm. A distance H2 between a lower surface of the light control layer LCL and a lower surface of the light emitting layer 172 may be in a range of about 5 μm to about 10 μm, but is not limited thereto. For example, the distance H2 between the lower surface of the light control layer LCL and the lower surface of the light emitting layer 172 may be about 8 μm.

In an embodiment, the light blocking film LS may include first to fourth louvers LV1, LV2, LV3, and LV4. Each of the first to fourth louvers LV1, LV2, LV3, and LV4 may extend in the second direction DR2. The first to fourth louvers LV1, LV2, LV3, and LV4 may be disposed to be spaced apart from each other in the first direction DR1.

The first louver LV1 may be disposed on one side or a side of the first and second emission areas PEA1 and PEA2 of the privacy mode area PEA in the first direction DR1. For example, the first louver LV1 may be disposed on the left side of the first and second emission areas PEA1 and PEA2 of the privacy mode area PEA in the drawings. The first louver LV1 may not overlap the first and second emission areas PEA1 and PEA2 in the third direction DR3.

The second louver LV2 may be disposed on one side or a side of the first louver LV1 in the first direction DR1. For example, the second louver LV2 may be disposed on the right side of the first louver LV1 in the drawings. The second louver LV2 may overlap the first and second emission areas PEA1 and PEA2 of the privacy mode area PEA in the third direction DR3.

The third louver LV3 may be disposed on one side or a side of the third emission area PEA3 of the privacy mode area PEA in the first direction DR1. For example, the third louver LV3 may be disposed on the left side of the third emission area PEA3 of the privacy mode area PEA in the drawings. The third louver LV3 may not overlap the third emission area PEA3 in the third direction DR3.

The fourth louver LV4 may be disposed on one side or a side of the third louver LV3 in the first direction DR1. For example, the fourth louver LV4 may be disposed on the right side of the third louver LV3 in the drawings. The fourth louver LV4 may overlap the third emission area PEA3 of the privacy mode area PEA in the third direction DR3.

The first louver LV1 and the second louver LV2 may be disposed on both sides of a first side of the first and second emission areas PEA1 and PEA2 of the privacy mode area PEA, respectively, with the first side between. For example, the first side of the first and second emission areas PEA1 and PEA2 may be a side positioned on the other side of the first and second emission areas PEA1 and PEA2 in the first direction DR1. Hereinafter, the first side may be referred to as a first reference line RFL1.

The third louver LV3 and the fourth louver LV4 may be disposed on both sides of a second side of the third emission area PEA3 of the privacy mode area PEA, respectively, with the second side between. For example, the second side of the third emission area PEA3 may be a side positioned on the other side of the third emission area PEA3 in the first direction DR1. Hereinafter, the second side may be referred to as a second reference line RFL2.

A third side of the first and second emission areas PEA1 and PEA2 may be positioned on a side opposite to the first side of the first and second emission areas PEA1 and PEA2. For example, the third side of the first and second emission areas PEA1 and PEA2 may be a side positioned on one side or a side of the first and second emission areas PEA1 and PEA2 in the first direction DR1. Hereinafter, the third side may be referred to as a third reference line RFL3.

A fourth side of the third emission area PEA3 may be positioned on a side opposite to the second side of the third emission area PEA3. For example, the fourth side of the third emission area PEA3 may be a side positioned on one side or a side of the third emission area PEA3 in the first direction DR1. Hereinafter, the fourth side may be referred to as a fourth reference line RFL4.

The non-transmissive area LSA may include first to fourth non-transmissive areas LSA1, LSA2, LSA3, and LSA4. The transmissive area OA may include first to fourth transmissive areas OA1, OA2, OA3, and OA4.

The first non-transmissive area LSA1 may be an area in which the first louver LV1 is disposed. The first non-transmissive area LSA1 may be an area overlapping the first louver LV1. The second non-transmissive area LSA2 may be an area in which the second louver LV2 is disposed. The second non-transmissive area LSA2 may be an area overlapping the second louver LV2. The third non-transmissive area LSA3 may be an area in which the third louver LV3 is disposed. The third non-transmissive area LSA3 may be an area overlapping the third louver LV3. The fourth non-transmissive area LSA4 may be an area in which the fourth louver LV4 is disposed. The fourth non-transmissive area LSA4 may be an area overlapping the fourth louver LV4.

The first transmissive area OA1 may be an area disposed between the first louver LV1 and the second louver LV2 in the first direction DR1. The first transmissive area OA1 may be disposed between the first non-transmissive area LSA1 and the second non-transmissive area LSA2 in the first direction DR1. The second transmissive area OA2 may be an area disposed between the second louver LV2 and the third louver LV3 in the first direction DR1. The second transmissive area OA2 may be disposed between the second non-transmissive area LSA2 and the third non-transmissive area LSA3 in the first direction DR1. The third transmissive area OA3 may be an area disposed between the third louver LV3 and the fourth louver LV4 in the first direction DR1. The third transmissive area OA3 may be disposed between the third non-transmissive area LSA3 and the fourth non-transmissive area LSA4 in the first direction DR1. The fourth transmissive area OA4 may be disposed on one side or a side of the fourth louver LV4 in the first direction DR1. The fourth transmissive area OA4 may be disposed on one side or a side of the fourth non-transmissive area LSA4 in the first direction DR1.

It has been illustrated in the drawings that the first and second louvers LV1 and LV2 are disposed adjacent to about the left side of the first and second emission areas PEA1 and PEA2 and the third and fourth louvers LV3 and LV4 are disposed adjacent to about the left side of the third emission area PEA3, but the disclosure is not limited thereto. For example, in case that a viewing angle from the display device 10 in front of the passenger seat toward the driver's seat is blocked, the louvers may be adjacent to about the left side of the emission areas, as illustrated in the drawings. However, in case that a viewing angle from the display device 10 in front of the driver's seat toward the passenger seat is blocked, the louvers may also be adjacent to about the right side of the emission areas. Depending on an application example of the display device 10, upper, lower, left, and right positions of the louvers may be freely modified within the same technical spirit.

Hereinafter, a positional relationship between the first to third emission areas PEA1, PEA2, and PEA3 of the privacy mode area PEA and the first to fourth louvers LV1, LV2, LV3, and LV4 will be described in detail with reference to FIGS. 9 to 11. Regarding the positional relationship between the first to third emission areas PEA1, PEA2, and PEA3 of the privacy mode area PEA and the first to fourth louvers LV1, LV2, LV3, and LV4, the same technical idea as the second emission area PEA2 may be applied to the first emission area PEA1, and thus, the second emission area PEA2 and the third emission area PEA3 will hereinafter be described by way of example.

In an embodiment, as described above with reference to FIG. 7, the width W3 of the second emission area PEA2 and the width W5 of the third emission area PEA3 in the first direction DR1 may be different from each other. For example, the width W3 of the second emission area PEA2 in the first direction DR1 may be greater than the width W5 of the third emission area PEA3 in the first direction DR1. Accordingly, a distance between the first reference line RFL1 and the third reference line RFL3 in the first direction DR1 may be greater than a distance between the second reference line RFL2 and the fourth reference line RFL4 in the first direction DR1.

In a case where the width W3 of the second emission area PEA2 is greater than the width W5 of the third emission area PEA3, in case that a distance L2 between the first reference line RFL1 of the second emission area PEA2 and the first louver LV1 and a distance L7 between the second reference line RFL2 of the third emission area PEA3 and the third louver LV3 are the same as each other and a distance L3 between the first reference line RFL1 of the second emission area PEA2 and the second louver LV2 and a distance L8 between the second reference line RFL2 of the third emission area PEA3 and the fourth louver LV4 are the same as each other, as the viewing angle gradually increases, a point in time in case that the emission area is completely obscured by the louver may occur earlier in the third emission area PEA3 than in the second emission area PEA2. FIGS. 9, 10, 15 and 16 also include distances L1 and L4.

For example, in case that the distance L2 between the first reference line RFL1 of the second emission area PEA2 and the first louver LV1 and the distance L7 between the second reference line RFL2 of the third emission area PEA3 and the third louver LV3 are the same as each other and the distance L3 between the first reference line RFL1 of the second emission area PEA2 and the second louver LV2 and the distance L8 between the second reference line RFL2 of the third emission area PEA3 and the fourth louver LV4 are the same as each other, a left area of the second emission area PEA2 with respect to the second louver LV2 and a left area of the third light emission area PEA3 with respect to the fourth louver LV4 may be the same as each other. On the other hand, the width W3 of the second emission area PEA2 is greater than the width W5 of the third emission area PEA3, and thus, a distance L5 between the third reference line RFL3 and the second louver LV2 may be greater than a distance L10 between the fourth reference line RFL4 and the fourth louver LV4. For example, a right area of the second emission area PEA2 with respect to the second louver LV2 may be greater than a right area of the third emission area PEA3 with respect to the fourth louver LV4. Accordingly, as the viewing angle gradually increases, a point in time in case that the emission area is completely obscured by the louver may occur earlier in the third emission area PEA3 than in the second emission area PEA2.

Accordingly, as the viewing angle reaches a given angle and increases, a color deviation phenomenon in which only a color of the second emission areas PEA1 and PEA2 is viewed may occur. For example, in case that the first to third emission areas PEA1, PEA2, and PEA3 emit red light, green light, and blue light, respectively, a point in time in case that the third emission area PEA3 is completely obscured is reached first, and thus, a yellowish phenomenon in which the red light and the green light emitted by the first and second emission areas PEA1 and PEA2 are mixed with each other, such that yellow is viewed may occur.

In the display device 10 according to an embodiment, it is possible to minimize such a color deviation phenomenon by making the distances L2 and L3 between the first reference line RFL1 and the first and second louvers LV1 and LV2 and the distances L7 and L8 between the second reference line RFL2 and the third and fourth louvers LV3 and LV4 different from each other.

For example, a positional relationship between the first louver LV1 and the second louver LV2 with respect to the first reference line RFL1 and a positional relationship between the third louver LV3 and the fourth louver LV4 with respect to the second reference line RFL2 may be different from each other.

In an embodiment, the distance L2 between the first reference line RFL1 and the first louver LV1 in the first direction DR1 may be different from the distance L7 between the second reference line RFL2 and the third louver LV3 in the first direction DR1. For example, the distance L2 between the first reference line RFL1 and the first louver LV1 in the first direction DR1 may be smaller than the distance L7 between the second reference line RFL2 and the third louver LV3 in the first direction DR1. For example, a distance by which the first louver LV1 is spaced apart from the first reference line RFL1 in the first direction DR1 may be smaller than a distance by which the third louver LV3 is spaced apart from the second reference line RFL2 in the first direction DR1. Accordingly, a distance by which the first louver LV1 is spaced apart from the second emission area PEA2 in the first direction DR1 may be smaller than a distance by which the third louver LV3 is spaced apart from the third emission area PEA3 in the first direction DR1. A length of a portion where the first transmissive area OA1 does not overlap the second emission area PEA2 in the first direction DR1 may be smaller than a length of a portion where the third transmissive area OA3 does not overlap the third emission area PEA3 in the first direction DR1.

Accordingly, as the viewing angle increases, a point in time in case that the third emission area PEA3 is completely obscured by the third and fourth louvers LV3 and LV4 may be delayed to become close to a point in time in case that the second emission area PEA2 is completely obscured by the first and second louvers LV1 and LV2. Accordingly, the color deviation phenomenon may be minimized.

In an embodiment, the distance L3 between the first reference line RFL1 and the second louver LV2 in the first direction DR1 may be different from the distance L8 between the second reference line RFL2 and the fourth louver LV4 in the first direction DR1. For example, the distance L3 between the first reference line RFL1 and the second louver LV2 in the first direction DR1 may be greater than the distance L8 between the second reference line RFL2 and the fourth louver LV4 in the first direction DR1. For example, a length by which the first transmissive area OA1 overlaps the second emission area PEA2 in the first direction DR1 may be greater than a length by which the third transmissive area OA3 overlaps the third emission area PEA3 in the first direction DR1.

Accordingly, a length by which the third emission area PEA3 overlaps the fourth transmissive area OA4 increases, such that as the viewing angle increases, a point in time in case that the third emission area PEA3 is completely obscured by the third and fourth louvers LV3 and LV4 may be delayed to become close to a point in time in case that the second emission area PEA2 is completely obscured by the first and second louvers LV1 and LV2. Accordingly, the color deviation phenomenon may be minimized.

In an embodiment, the distance L5 between the third reference line RFL3 and the second louver LV2 in the first direction DR1 may be different from the distance L10 between the fourth reference line RFL4 and the fourth louver LV4 in the first direction DR1. For example, the distance L5 between the third reference line RFL3 and the second louver LV2 in the first direction DR1 may be greater than the distance L10 between the fourth reference line RFL4 and the fourth louver LV4 in the first direction DR1. For example, a length by which the second transmissive area OA2 overlaps the second emission area PEA2 in the first direction DR1 may be greater than a length by which the fourth transmissive area OA4 overlaps the third emission area PEA3 in the first direction DR1.

In the display device 10 according to an embodiment, the distance L5 between the third reference line RFL3 and the second louver LV2 is greater than the distance L10 between the fourth reference line RFL4 and the fourth louver LV4, and thus, simply in terms of distance, a point in time in case that a right portion of the third emission area PEA3 is completely obscured by the fourth louver LV4 may be still earlier than a point in time in case that a right portion of the second emission area PEA2 is completely obscured by the second louver LV2. However, as described above, a degree to which a left portion of the third emission area PEA3 is obscured by the third louver LV3 may be alleviated due to an effect that the third louver LV3 moves to the left. Accordingly, even though the distance L5 between the third reference line RFL3 and the second louver LV2 is greater than the distance L10 between the fourth reference line RFL4 and the fourth louver LV4, the color deviation phenomenon may be minimized.

In an embodiment, widths L1, L4, L6, and L9 of the first to fourth louvers LV1, LV2, LV3, and LV4 may be the same as each other. For example, the widths L1, L4, L6, and L9 of the first to fourth louvers LV1, LV2, LV3, and LV4 may be in a range of about 2 μm to about 10 μm. For example, the widths L1, L4, L6, and L9 of the first to fourth louvers LV1, LV2, LV3, and LV4 may be about 4 μm. A distance between the first and second louvers LV1 and LV2 may be the same as a distance between the third and fourth louvers LV3 and LV4. For example, a length of the first transmissive area OA1 in the first direction DR1 may be the same as a length of the third transmissive area OA3 in the first direction DR1. For example, the distance between the first and second louvers LV1 and LV2 and the distance between the third and fourth louvers LV3 and LV4 may be in a range of about 5 μm to about 20 μm, but are not limited thereto.

Hereinafter, a color deviation improvement effect of the display device 10 according to an embodiment will be described by comparing luminance values according to viewing angles of a display device 10 according to the related art and the display device 10 according to an embodiment with each other.

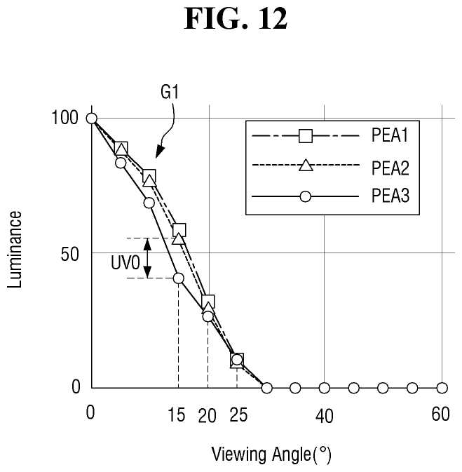

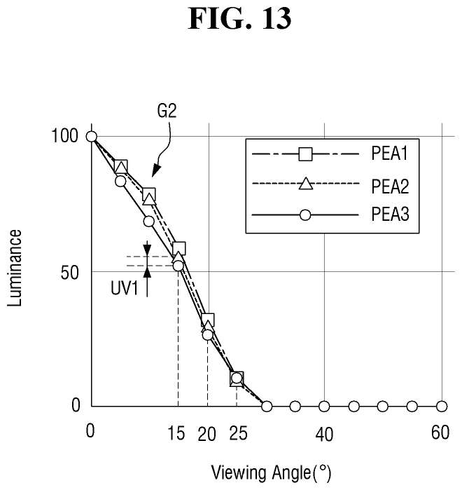

FIG. 12 is a graph illustrating luminance values of emission areas according to a viewing angle in a display device according to the related art. FIG. 13 is a graph illustrating luminance values of emission areas according to a viewing angle in the display device according to an embodiment.

Referring to FIGS. 12 and 13 and FIGS. 8 to 11, a first graph G1 and a second graph G2 are graphs illustrating changes in luminance of the first to third emission areas PEA1, PEA2, and PEA3 of the privacy mode area PEA according to changes in viewing angles.

The first graph G1 illustrates a change in luminance in the display device 10 according to the related art, and the second graph G2 illustrates a change in luminance in the display device 10 according to an embodiment. The display device 10 according to the related art is different from the display device 10 according to an embodiment in that the distances L2 and L3 between the first reference line RFL1 and the first and second louvers LV1 and LV2 and the distances L7 and L8 between the second reference line RFL2 and the third and fourth louvers LV3 and LV4 are the same as each other.

According to the first graph G1, it can be seen that in case that the viewing angle is about 15°, a luminance difference occurs between the first and second emission areas PEA1 and PEA2 and the third emission area PEA3. Due to such a luminance difference, white and black may not be clearly expressed, and a deviation may occur toward colors emitted by the first and second emission areas PEA1 and PEA2.

For example, at the viewing angle of about 15°, a luminance difference between the first and second emission areas PEA1 and PEA2 and the third emission area PEA3 corresponding to a first difference value UV0 may occur. In this case, a Δu′v′ value may be about 0.019. At a viewing angle of about 20°, the Δu′v′ value may be about 0.014, and at a viewing angle of about 25°, the Δu′v′ value may be about 0.019.

In the specification, such values refer to values measured based on the CIE 1976 color coordinate system.

According to the second graph G2, it can be seen that in case that the viewing angle is about 15°, a luminance difference does not almost occur between the first and second emission areas PEA1 and PEA2 and the third emission area PEA3.

For example, at the viewing angle of about 15°, a luminance difference between the first and second emission areas PEA1 and PEA2 and the third emission area PEA3 corresponding to a second difference value UV1 may occur. In this case, a Δu′v′ value may be about 0.002. At a viewing angle of about 20°, the Δu′v′ value may be about 0.004, and at a viewing angle of about 25°, the Δu′v′ value may be about 0.019.

As such, in the display device 10 according to an embodiment, it is possible to minimize such a color deviation phenomenon by making the distances L2 and L3 between the first reference line RFL1 and the first and second louvers LV1 and LV2 and the distances L7 and L8 between the second reference line RFL2 and the third and fourth louvers LV3 and LV4 different from each other.

Hereinafter, other embodiments of the display device according to an embodiment will be described. In the following embodiments, the same components as those of the above-described embodiment will be denoted by the same reference numerals, and an overlapping description thereof may be omitted or simplified and contents different from those described above will be described.

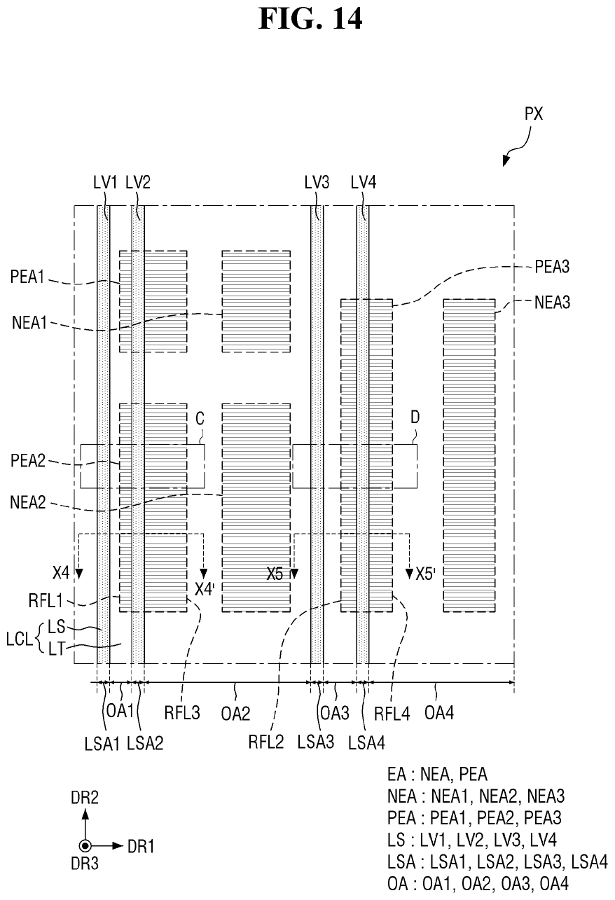

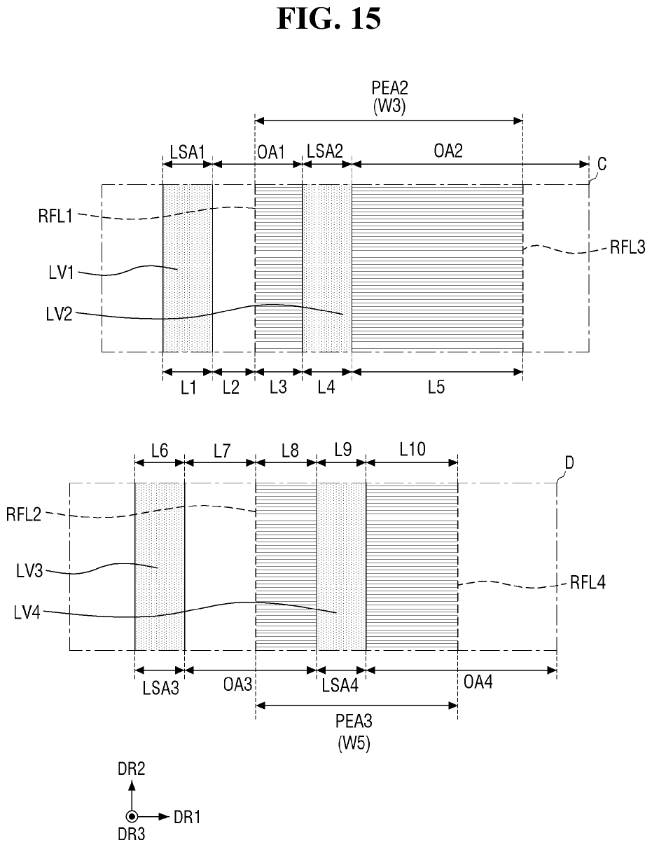

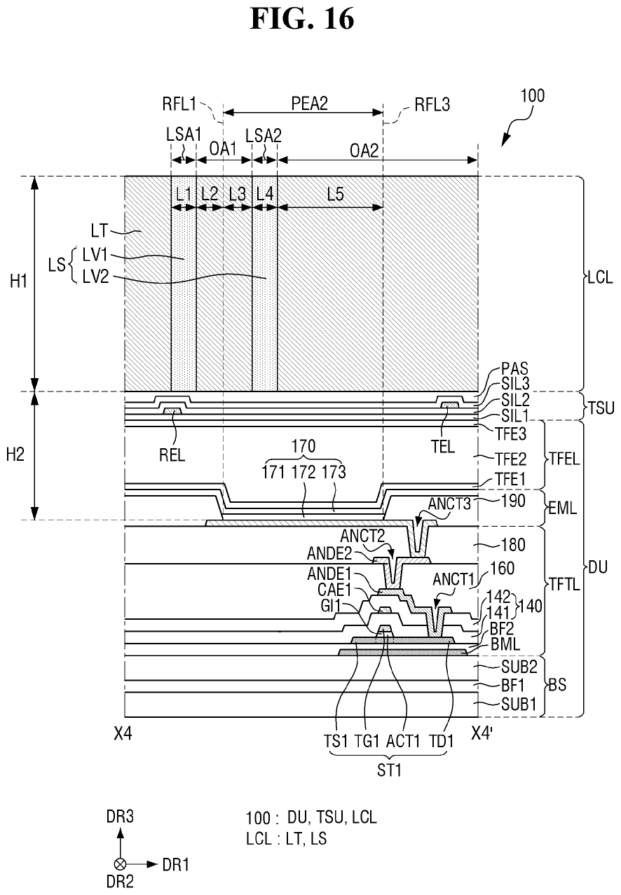

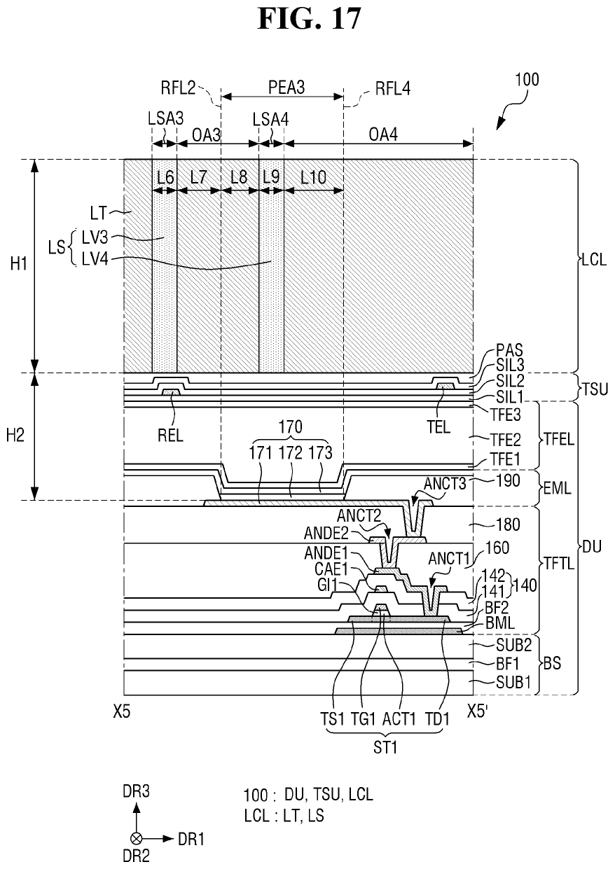

FIG. 14 is a schematic plan view illustrating a pixel and a light control layer of the display device according to an embodiment. FIG. 15 is an enlarged comparison view of area A and area B of FIG. 14. FIG. 16 is a schematic cross-sectional view of the display panel taken along line X4-X4′ of FIG. 14. FIG. 17 is a schematic cross-sectional view of the display panel taken along line X5-X5′ of FIG. 14.

Referring to FIGS. 14 to 17, a display device 10 according to an embodiment may be different from the display device 10 according to an embodiment described with reference to FIG. 8 and the like in that a distance between the first and second louvers LV1 and LV2 and a distance between the third and fourth louvers LV3 and LV4 are different from each other.

By way of example, in the display device 10 according to an embodiment, it is possible to minimize a color deviation phenomenon by making the distances L2 and L3 between the first reference line RFL1 and the first and second louvers LV1 and LV2 and the distances L7 and L8 between the second reference line RFL2 and the third and fourth louvers LV3 and LV4 different from each other, like the display device 10 according to an embodiment described with reference to FIG. 8 and the like within the spirit and the scope of the disclosure.

For example, a positional relationship between the first louver LV1 and the second louver LV2 with respect to the first reference line RFL1 and a positional relationship between the third louver LV3 and the fourth louver LV4 with respect to the second reference line RFL2 may be different from each other.

However, in the display device 10 according to an embodiment, the distance between the first and second louvers LV1 and LV2 and the distance between the third and fourth louvers LV3 and LV4 may be different from each other, unlike the display device 10 according to an embodiment described with reference to FIG. 8 and the like within the spirit and the scope of the disclosure.

For example, in the display device 10 according to an embodiment described with reference to FIG. 8 and the like, it is possible to make the distances L2 and L3 between the first reference line RFL1 and the first and second louvers LV1 and LV2 and the distances L7 and L8 between the second reference line RFL2 and the third and fourth louvers LV3 and LV4 different from each other while keeping the distance between the first and second louvers LV1 and LV2 and the distance between the third and fourth louvers LV3 and LV4 the same as each other. On the other hand, in the display device 10 according to an embodiment, it is possible to further minimize the color deviation phenomenon by not only making the distances L2 and L3 between the first reference line RFL1 and the first and second louvers LV1 and LV2 and the distances L7 and L8 between the second reference line RFL2 and the third and fourth louvers LV3 and LV4 different from each other but also making the distance between the first and second louvers LV1 and LV2 and the distance between the third and fourth louvers LV3 and LV4 different from each other.

By way of example, the distance between the first and second louvers LV1 and LV2 may be different from the distance between the third and fourth louvers LV3 and LV4. For example, the distance between the first and second louvers LV1 and LV2 may be smaller than the distance between the third and fourth louvers LV3 and LV4. For example, a length of the first transmissive area OA1 in the first direction DR1 may be smaller than a length of the third transmissive area OA3 in the first direction DR1.

In an embodiment, the distance L2 between the first reference line RFL1 and the first louver LV1 in the first direction DR1 may be different from the distance L7 between the second reference line RFL2 and the third louver LV3 in the first direction DR1. For example, the distance L2 between the first reference line RFL1 and the first louver LV1 in the first direction DR1 may be smaller than the distance L7 between the second reference line RFL2 and the third louver LV3 in the first direction DR1. For example, a distance by which the first louver LV1 is spaced apart from the first reference line RFL1 in the first direction DR1 may be smaller than a distance by which the third louver LV3 is spaced apart from the second reference line RFL2 in the first direction DR1. Accordingly, a distance by which the first louver LV1 is spaced apart from the second emission area PEA2 in the first direction DR1 may be smaller than a distance by which the third louver LV3 is spaced apart from the third emission area PEA3 in the first direction DR1. A length of a portion where the first transmissive area OA1 does not overlap the second emission area PEA2 in the first direction DR1 may be smaller than a length of a portion where the third transmissive area OA3 does not overlap the third emission area PEA3 in the first direction DR1.

Accordingly, a point in time in case that the third emission area PEA3 is completely obscured by the third and fourth louvers LV3 and LV4 may be delayed to become close to a point in time in case that the second emission area PEA2 is completely obscured by the first and second louvers LV1 and LV2. Accordingly, the color deviation phenomenon may be minimized.

In an embodiment, the distance L3 between the first reference line RFL1 and the second louver LV2 in the first direction DR1 may be different from the distance L8 between the second reference line RFL2 and the fourth louver LV4 in the first direction DR1. For example, the distance L3 between the first reference line RFL1 and the second louver LV2 in the first direction DR1 may be smaller than the distance L8 between the second reference line RFL2 and the fourth louver LV4 in the first direction DR1. For example, a length by which the first transmissive area OA1 overlaps the second emission area PEA2 in the first direction DR1 may be smaller than a length by which the third transmissive area OA3 overlaps the third emission area PEA3 in the first direction DR1.

Accordingly, a length by which the third emission area PEA3 overlaps the third transmissive area OA3 increases, such that as the viewing angle increases, a point in time in case that the third emission area PEA3 is completely obscured by the fourth louver LV4 may be delayed to become close to a point in time in case that the second emission area PEA2 is completely obscured by the first and second louvers LV1 and LV2. Accordingly, the color deviation phenomenon may be minimized.

In an embodiment, the distance L5 between the third reference line RFL3 and the second louver LV2 in the first direction DR1 may be different from the distance L10 between the fourth reference line RFL4 and the fourth louver LV4 in the first direction DR1. For example, the distance L5 between the third reference line RFL3 and the second louver LV2 in the first direction DR1 may be greater than the distance L10 between the fourth reference line RFL4 and the fourth louver LV4 in the first direction DR1. For example, a length by which the second transmissive area OA2 overlaps the second emission area PEA2 in the first direction DR1 may be greater than a length by which the fourth transmissive area OA4 overlaps the third emission area PEA3 in the first direction DR1.

In the display device 10 according to an embodiment, the distance L5 between the third reference line RFL3 and the second louver LV2 is greater than the distance L10 between the fourth reference line RFL4 and the fourth louver LV4, and thus, simply in terms of distance, a point in time in case that a right portion of the third emission area PEA3 is completely obscured by the fourth louver LV4 may be still earlier than a point in time in case that a right portion of the second emission area PEA2 is completely obscured by the second louver LV2. However, as described above, a degree to which a left portion of the third emission area PEA3 is obscured by the third louver LV3 may be alleviated due to an effect that the third louver LV3 moves to the left. Accordingly, even though the distance L5 between the third reference line RFL3 and the second louver LV2 is greater than the distance L10 between the fourth reference line RFL4 and the fourth louver LV4, the color deviation phenomenon may be minimized.

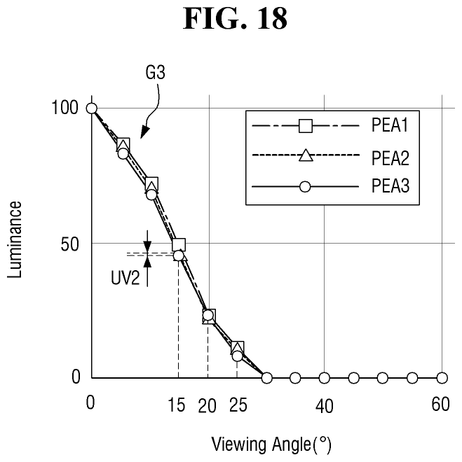

FIG. 18 is a graph illustrating luminance values of emission areas according to a viewing angle in the display device according to an embodiment.

Referring to FIG. 18 and FIGS. 14 to 17, a third graph G3 and a second graph G2 are a graph illustrating changes in luminance of the first to third emission areas PEA1, PEA2, and PEA3 of the privacy mode area PEA according to a change in viewing angle.

According to the third graph G3, it can be seen that in case that the viewing angle is about 15°, a luminance difference does not almost occur between the first and second emission areas PEA1 and PEA2 and the third emission area PEA3.

For example, at the viewing angle of about 15°, a luminance difference between the first and second emission areas PEA1 and PEA2 and the third emission area PEA3 corresponding to a third difference value UV2 may occur. In this case, a Δu′v′ value may be about 0.003. At a viewing angle of about 20°, the Δu′v′ value may be about 0.008, and at a viewing angle of about 25°, the Δu′v′ value may be about 0.008. It can be seen that at the viewing angle of about 25°, the color deviation phenomenon is further improved compared to the display device 10 according to an embodiment described with reference to FIG. 8 and the like within the spirit and the scope of the disclosure.

In the display device 10 according to an embodiment, it is possible to further minimize such a color deviation phenomenon by making the distances L2 and L3 between the first reference line RFL1 and the first and second louvers LV1 and LV2 and the distances L7 and L8 between the second reference line RFL2 and the third and fourth louvers LV3 and LV4 different from each other and making the distance between the first and second louvers LV1 and LV2 and the distance between the third and fourth louvers LV3 and LV4 different from each other.

In concluding the detailed description, those skilled in the art will appreciate that many variations and modifications can be made to the disclosed embodiments without substantially departing from the principles of the disclosure. Therefore, the disclosed embodiments are used in a generic and descriptive sense only and not for purposes of limitation.

What is claimed is:

1. A display device comprising:
a light emitting element layer disposed on a substrate, the light emitting element layer including a first light emitting element and a second light emitting element;
a light control layer disposed on the light emitting element layer, the light control layer including a plurality of light blocking films spaced apart from each other and a light transmitting film disposed between the plurality of light blocking films; and
a first emission area and a second emission area through which light emitted from the first light emitting element and the second light emitting element are emitted, respectively, wherein
the plurality of light blocking films include:
a first louver and a second louver disposed on both sides of a first side of the first emission area, respectively, with the first side disposed between the first louver and the second louver; and
a third louver and a fourth louver disposed on both sides of a second side of the second emission area, respectively, with the second side disposed between the third louver and the fourth louver,
a width of the first emission area is different from a width of the second emission area, and
a distance between the first side and the first louver is different from a distance between the second side and the third louver.

2. The display device of claim 1, wherein the width of the first emission area is greater than the width of the second emission area.

3. The display device of claim 2, wherein a distance between the first louver and the second louver and a distance between the third louver and the fourth louver are the same.

4. The display device of claim 3, wherein the distance between the first side and the first louver is less than the distance between the second side and the third louver.

5. The display device of claim 4, wherein widths of the first louver, the second louver, the third louver and the fourth louver are the same.

6. The display device of claim 4, wherein a length of a portion where the light transmitting film disposed between the first louver and the second louver does not overlap the first emission area is less than a length of a portion where the light transmitting film disposed between the third louver and the fourth louver does not overlap the second emission area.

7. The display device of claim 3, wherein a length by which the light transmitting film disposed between the first louver and the second louver overlaps the first emission area is greater than a length by which the light transmitting film disposed between the third louver and the fourth louver overlaps the second emission area.

8. The display device of claim 2, wherein a distance between the first side and the second louver is different from a distance between the second side and the fourth louver.

9. The display device of claim 8, wherein the distance between the first side and the second louver is greater than the distance between the second side and the fourth louver.

10. The display device of claim 2, wherein
the first emission area includes a third side disposed on a side opposite to the first side with the second louver disposed between the third side and the side opposite to the first side, and
the second emission area includes a fourth side disposed on a side opposite to the second side with the fourth louver disposed between the fourth side and the side opposite to the second side.

11. The display device of claim 10, wherein a distance between the third side and the second louver is greater than a distance between the fourth side and the fourth louver.

12. The display device of claim 1, wherein
the first louver does not overlap the first emission area, and
the third louver does not overlap the second emission area.

13. The display device of claim 1, wherein
the second louver overlaps the first emission area, and
the fourth louver overlaps the second emission area.

14. A display device comprising:
a light emitting element layer disposed on a substrate, the light emitting element layer including a first light emitting element and a second light emitting element;
a light control layer disposed on the light emitting element layer, the light control layer including a plurality of light blocking films spaced apart from each other and a light transmitting film disposed between the plurality of light blocking films; and
a first emission area and a second emission area through which light emitted from the first light emitting element and the second light emitting element are emitted, respectively, wherein
the plurality of light blocking films include:
a first louver and a second louver disposed on both sides of a first side of the first emission area, respectively, with the first side disposed between the first louver and the second louver; and
a third louver and a fourth louver disposed on both sides of a second side of the second emission area, respectively, with the second side disposed between the third louver and the fourth louver,
a width of the first emission area is different from a width of the second emission area, and
a distance between the first louver and the second louver is different from a distance between the third louver and the fourth louver.

15. The display device of claim 14, wherein the width of the first emission area is greater than the width of the second emission area.

16. The display device of claim 15, wherein the distance between the first louver and the second louver is less than the distance between the third louver and the fourth louver

17. The display device of claim 16, wherein a distance between the first side and the first louver is less than a distance between the second side and the third louver.

18. The display device of claim 17, wherein widths of the first louver, the second louver, the third louver and the fourth louver are the same.

19. The display device of claim 17, wherein a length of a portion where the light transmitting film disposed between the first louver and the second louver does not overlap the first emission area is less than a length of a portion where the light transmitting film disposed between the third louver and the fourth louver does not overlap the second emission area.

20. The display device of claim 15, wherein a distance between the first side and the second louver is different from a distance between the second side and the fourth louver.

21. The display device of claim 20, wherein the distance between the first side and the second louver is less than the distance between the second side and the fourth louver.

22. The display device of claim 15, wherein the first emission area includes a third side disposed on a side opposite to the first side with the second louver disposed between the third side and the side opposite to the first side, and
the second emission area includes a fourth side disposed on a side opposite to the second side with the fourth louver disposed between the fourth side and the side opposite to the second side.

23. The display device of claim 22, wherein a distance between the third side and the second louver is greater than a distance between the fourth side and the fourth louver.

24. The display device of claim 14, wherein the first louver does not overlap the first emission area, and
the third louver does not overlap the second emission area.

25. The display device of claim 14, wherein the second louver overlaps the first emission area, and the fourth louver overlaps the second emission area.
